(19) United States
(12) Patent Application Publication
(10) Pub. No.: US 2025/0089504 A1
(43) Pub. Date: Mar. 13, 2025

(54) Display Substrate and Preparation Method therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Tinghua SHANG, Beijing (CN); Yi ZHANG, Beijing (CN); Yang ZHOU, Beijing (CN); Yixuan LONG, Beijing (CN); Yuanqi ZHANG, Beijing (CN)

(21) Appl. No.: 18/279,384

(22) PCT Filed: Oct. 31, 2022
(86) PCT No.: PCT/CN2022/128721

§ 371 Date: Aug. 29, 2023

(51) Int. Cl. H10K 59/131; H10K 59/12; H10K 59/121

(52) U.S. Cl. CPC H10K 59/1315; H10K 59/1201; H10K 59/1213; H10K 59/1216

(57) ABSTRACT

Disclosed are a display substrate and a preparation method therefor, and a display apparatus. The display substrate includes a plurality of circuit units, a plurality of data signal lines extending along a second direction, a plurality of first connection lines, and a plurality of second connection lines; a circuit unit includes a pixel drive circuit, at least one data signal line is connected with a plurality of pixel drive circuits of a unit column, first ends of the plurality of first connection lines are correspondingly connected with the plurality of data signal lines, and second ends of the plurality of first connection lines are correspondingly connected with the plurality of second connection lines; pixel drive circuits in adjacent unit columns are mirror symmetrical with respect to a center line, and a second connection line is disposed at a gap between pixel drive circuits in adjacent unit columns.

### CROSS-REFERENCE TO RELATED APPLICATION

The present application is a U.S. National Phase Entry of International Application No. PCT/CN2022/128721 having an international filing date of Oct. 31, 2022. The entire contents of the above-identified application are hereby incorporated by reference.

### TECHNICAL FIELD

The present disclosure relates to, but is not limited to, the field of display technologies, and particularly to a display substrate and a preparation method therefor, and a display apparatus.

### BACKGROUND

An Organic Light Emitting Diode (OLED for short) and a Quantum dot Light Emitting Diode (QLED for short) are active light emitting display devices and have advantages such as self-luminescence, a wide viewing angle, a high contrast ratio, low power consumption, an extremely high response speed, lightness and thinness, flexibility, and a low cost. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matter described herein in detail. The summary is not intended to limit the protection scope of claims.

In one aspect, the present disclosure provides a display substrate including a display region, wherein the display region includes a drive structure layer disposed on the base substrate, the drive structure layer at least includes a plurality of circuit units constituting a plurality of unit rows and a plurality of unit columns, a plurality of data signal lines extending along a second direction, a plurality of first connection lines extending along a first direction, and a plurality of second connection lines extending along the second direction, the first direction intersects with the second direction; a circuit unit includes a pixel drive circuit, at least one data signal line is connected with a plurality of pixel drive circuits of a unit column, first ends of the plurality of first connection lines are correspondingly connected with the plurality of data signal lines, and second ends of the plurality of first connection lines are correspondingly connected with the plurality of second connection lines; pixel drive circuits in adjacent unit columns are mirror symmetrical with respect to a center line, the center line is a straight line located between adjacent unit columns and extending along the second direction, and a second connection line is disposed at a gap between pixel drive circuits of adjacent unit columns.

In an exemplary implementation mode, two data signal lines in at least one adjacent unit column are mirror symmetrical with respect to the second connection line, and a minimum distance between the second connection line and an adjacent data signal line in the first direction is greater than a minimum distance between the two data signal lines in the adjacent unit columns in the first direction.

In an exemplary implementation mode, two data signal lines in at least one adjacent unit column are mirror symmetrical with respect to the second connection line, and a minimum distance between the second connection line and an adjacent data signal line in the first direction is ½ of a minimum distance between the two data signal lines in the adjacent unit columns in the first direction.

In an exemplary implementation mode, the drive structure layer further includes a plurality of power supply traces extending along the second direction, and a power supply traces is disposed at a gap between pixel drive circuits of adjacent unit columns.

In an exemplary implementation mode, two data signal lines in at least one adjacent unit column are mirror symmetrical with respect to the power supply trace, and a minimum distance between the power supply trace and an adjacent data signal line in the first direction is greater than a minimum distance between the two data signal lines in the adjacent unit columns in the first direction.

In an exemplary implementation mode, two data signal lines in at least one adjacent unit column are mirror symmetrical with respect to the power supply trace, and a minimum distance between the power supply trace and an adjacent data signal line in the first direction is ½ of a minimum distance between the two data signal lines in the adjacent unit columns in the first direction.

In an exemplary implementation mode, on a plane perpendicular to the display substrate, the drive structure layer includes a plurality of conductive layers disposed sequentially on the base substrate, a first connection line and a second connection line are disposed in different conductive layers, and a data signal line and the second connection line are disposed in a same conductive layer.

In an exemplary implementation mode, the plurality of conductive layers at least include a first source-drain metal layer, a second source-drain metal layer, and a third source-drain metal layer that are sequentially disposed along a direction away from the base substrate, the first connection line is disposed in the second source-drain metal layer, the data signal line and the second connection line are disposed in the third source-drain metal layer, the data signal line is connected with a first end of the first connection line through a via, and the second connection line being connected with a second end of the first connection line through a via.

In an exemplary implementation mode, the pixel drive circuit at least includes a first transistor, a second transistor, and a storage capacitor, the first transistor at least includes a first active layer, the second transistor at least includes a second active layer, a second region of the first active layer and the first region of the second active layer are of an interconnected integral structure, and are connected with a first electrode plate of the storage capacitor through a first connection electrode; the second source-drain metal layer further includes a shielding electrode, an orthographic projection of the shielding electrode on the base substrate is at least partially overlapped with an orthographic projection of the second region of the first active layer and the first region of the second active layer on the base substrate, and the orthographic projection of the shielding electrode on the base substrate is at least partially overlapped with an orthographic projection of the first connection electrode on the base substrate.

In an exemplary implementation mode, the third source-drain metal layer further includes a first power supply line, and the first power supply line is connected with the shielding electrode through a via.

In an exemplary implementation mode, on a plane perpendicular to the display substrate, the display substrate further includes a light emitting structure layer disposed on a side of the drive structure layer away from the base substrate, the light emitting structure layer includes a plurality of light emitting units, a light emitting unit at least includes an anode; in at least one light emitting unit, an orthographic projection of the anode on the base substrate is at least partially overlapped with an orthographic projection of the first power supply line on the base substrate, and the orthographic projection of the anode on the base substrate is at least partially overlapped with the orthographic projection of the shielding electrode on the base substrate.

In an exemplary implementation mode, in at least one light emitting unit, an orthographic projection of the anode on the base substrate and the orthographic projection of the first power supply line on the base substrate have a first overlapping region, and the orthographic projection of the anode on the base substrate and the orthographic projection of the shielding electrode on the base substrate have a second overlapping region, and an area of the first overlapping region is less than an area of the second overlapping region.

In an exemplary implementation mode, the pixel drive circuit at least includes a fourth transistor, a first electrode of the fourth transistor is connected with the data signal line through a data connection electrode, and in at least one circuit unit, the first connection line is connected with the data connection electrode.

In an exemplary implementation mode, at least one circuit unit further includes a data connection block, a first end of the data connection block is connected with the first connection line, and a second end of the data connection block is connected with the data connection electrode.

In an exemplary implementation mode, in at least one circuit unit, the first connection line, the data connection electrode, and the data connection block are disposed in a same layer and are of an interconnected integral structure.

In an exemplary implementation mode, at least one circuit unit further includes a second initial signal line extending along the first direction and a second initial connection line extending along the second direction, the second initial connection line is disposed between two adjacent second initial signal lines in the second direction and is respectively connected with the two second initial signal lines to form a second initial signal line with a network communication structure in the display region.

In an exemplary implementation mode, the second initial connection line is disposed in an odd-numbered unit column, or the second initial connection line is disposed in an even-numbered unit column.

In an exemplary implementation mode, in two adjacent unit rows, a unit column in which the second initial connection line is located in one unit row is different from a unit column in which the second initial connection line is located in the other unit row.

In an exemplary implementation mode, the second initial signal line and the second initial connection line are disposed in a same layer and are of an interconnected integral structure.

In an exemplary implementation mode, the pixel drive circuit at least includes a storage capacitor and a plurality of transistors, the plurality of conductive layers include a shielding layer, a first semiconductor layer, a first gate metal layer, a second gate metal layer, a second semiconductor layer, a third gate metal layer, a first source-drain metal layer, a second source-drain metal layer, and a third source-drain metal layer that are sequentially disposed along a direction away from the base substrate; the shielding layer at least includes a shielding electrode, the first semiconductor layer at least includes active layers of a plurality of low temperature poly silicon transistors, the first gate metal layer at least includes a first scan signal line, a light emitting signal line, and a first electrode plate of a storage capacitor, the second gate metal layer at least includes a second electrode plate of the storage capacitor, the second semiconductor layer at least includes active layers of a plurality of oxide transistors, the third gate metal layer at least includes a second scan signal line and a third scan signal line, the first source-drain metal layer at least includes a second initial signal line with a network communication structure, the second source-drain metal layer at least includes a shielding electrode and the first connection line, and the third source-drain metal layer at least includes a first power supply line, the data signal line, and the second connection line.

In an exemplary implementation mode, the plurality of transistors include a first transistor, a second transistor, a third transistor, a fourth transistor, a fifth transistor, a sixth transistor, and a seventh transistor, the first transistor and the second transistor are oxide transistors, and the third transistor, the fourth transistor, the fifth transistor, the sixth transistor, and the seventh transistor are low temperature poly silicon transistors.

In another aspect, the present disclosure also provides a display apparatus, including the aforementioned display substrate.

In yet another aspect, the present disclosure also provides a preparation method of a display substrate, the display substrate includes a display region, and the preparation method includes: forming a drive structure layer on a base substrate of the display region, wherein the drive structure layer at least includes a plurality of circuit units constituting a plurality of unit rows and a plurality of unit columns, a plurality of data signal lines extending along a second direction, a plurality of first connection lines extending along a first direction, and a plurality of second connection lines extending along the second direction, the first direction intersects with the second direction; a circuit unit includes a pixel drive circuit, at least one data signal line is connected with a plurality of pixel drive circuits of a unit column, first ends of the plurality of first connection lines are correspondingly connected with the plurality of data signal lines, and second ends of the plurality of first connection lines are correspondingly connected with the plurality of second connection lines; pixel drive circuits in adjacent unit columns are mirror symmetrical with respect to a center line, the center line is a straight line located between adjacent unit columns and extending along the second direction, and a second connection line is disposed at a gap between pixel drive circuits of adjacent unit columns.

Other aspects may be understood upon reading and understanding drawings and detailed description.

### BRIEF DESCRIPTION OF DRAWINGS

Accompanying drawings are used for providing understanding of technical solutions of the present disclosure, constitute a part of the specification, and are used for explaining the technical solutions of the present disclosure together with embodiments of the present disclosure, but do not constitute limitations on the technical solutions of the present disclosure.

FIG. 1 is a schematic diagram of a structure of a display apparatus.

FIG. 2 is a schematic diagram of a structure of a display substrate.

FIG. 3 is a schematic diagram of a planar structure of a display region in a display substrate.

FIG. 4 is a schematic diagram of a sectional structure of a display region in a display substrate.

FIG. 5 is a schematic diagram of an equivalent circuit of a pixel drive circuit.

FIG. 6 is a schematic diagram of a planar structure of a display substrate according to an exemplary embodiment of the present disclosure.

FIG. 7 is a schematic diagram of an arrangement of data connection lines according to an exemplary embodiment of the present disclosure.

FIG. 8 is a schematic diagram of a planar structure of a display substrate according to an exemplary embodiment of the present disclosure.

FIG. 9 is a schematic diagram after a pattern of a shield layer is formed according to an embodiment of the present disclosure.

FIG. 10 and FIG. 11 are schematic diagrams after a pattern of a first semiconductor layer is formed according to an embodiment of the present disclosure.

FIG. 12 and FIG. 13 are schematic diagrams after a pattern of a first conductive layer is formed according to an embodiment of the present disclosure.

FIG. 14 and FIG. 15 are schematic diagrams after a pattern of a second conductive layer is formed according to an embodiment of the present disclosure.

FIG. 16 and FIG. 17 are schematic diagrams after a pattern of a second semiconductor layer is formed according to an embodiment of the present disclosure.

FIG. 18 and FIG. 19 are schematic diagrams after a pattern of a third conductive layer is formed according to an embodiment of the present disclosure.

FIG. 20 is a schematic diagram after a pattern of a sixth insulation layer is formed according to an embodiment of the present disclosure.

FIG. 21 and FIG. 22 are schematic diagrams after a pattern of a fourth conductive layer is formed according to an embodiment of the present disclosure.

FIG. 23 is a schematic diagram after a pattern of a first planarization layer is formed according to an embodiment of the present disclosure.

FIG. 24 and FIG. 25 are schematic diagrams after a pattern of a fifth conductive layer is formed according to an embodiment of the present disclosure.

FIG. 26 is a schematic diagram after a pattern of a second planarization layer is formed according to an embodiment of the present disclosure.

FIG. 27 to FIG. 28 are schematic diagrams after a pattern of a sixth conductive layer is formed according to an embodiment of the present disclosure.

FIG. 29 is a schematic diagram after a pattern of a third planarization layer is formed according to an embodiment of the present disclosure.

FIG. 30 is a schematic diagram after a pattern of an anode conductive layer is formed according to an embodiment of the present disclosure.

FIG. 31 is a schematic diagram after a pattern of a pixel definition layer is formed according to an embodiment of the present disclosure.

FIG. 32 is a schematic diagram of a planar structure of another display substrate according to an embodiment of the present disclosure.

Reference signs are described as follows.

| | | |
|---|---|---|
| 11-first active layer; | 12-second active layer; | 13-third active layer; |
| 14-fourth active layer; | 15-fifth active layer; | 16-sixth active layer; |
| 17-seventh active | 21-first scan signal | 22-light emitting |
| layer; | line; | signal line; |
| 23-first electrode plate; | 31-first initial signal | 32-second shielding |
| | line; | line; |
| 33-third shielding line; | 34-second electrode | 35-opening; |
| | plate; | |
| 41-second scan signal | 42-third scan signal line; | 51-first connection |
| line; | | electrode; |
| 52-second connection | 53-third connection | 54-fourth connection |
| electrode; | electrode; | electrode; |
| 55-fifth connection | 56-sixth connection | 57-second initial signal |
| electrode; | electrode; | line; |
| 58-second initial | 60-data signal line; | 61-eleventh connection |
| connection line; | | electrode; |
| 62-twelfth connection | 63-shielding electrode; | 64-first power supply |
| electrode; | | line; |
| 65-anode connection | 70-first connection line; | 71-first lap block; |
| electrode; | | |
| 72-data connection | 80-second connection | 81-second lap block; |
| block; | line; | |
| 90-power supply trace; | 91-first shielding | 92-second shielding |
| | connection line; | connection line; |
| 93-third shielding | 94-shielding electrode; | 100-display region; |
| connection line; | | |
| 101-base substrate; | 102-drive structure layer; | 103-light emitting |
| | | structure layer; |
| 104-encapsulation | 200-bonding region; | 300-bezel region. |
| structure layer; | | |

### DETAILED DESCRIPTION

To make objectives, technical solutions, and advantages of the present disclosure clearer, the embodiments of the present disclosure will be described in detail with reference to the accompanying drawings. It is to be noted that implementation modes may be implemented in a plurality of different forms. Those of ordinary skills in the art may easily understand such a fact that modes and contents may be transformed into various forms without departing from the purpose and scope of the present disclosure. Therefore, the present disclosure should not be explained as being limited to contents described in following implementation modes only. The embodiments in the present disclosure and features in the embodiments may be combined randomly with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals such as “first”, “second”, and “third” in the specification are set to avoid confusion between constituent elements, but not to set a limit in quantity.

In the specification, for convenience, wordings indicating orientation or positional relationships, such as “middle”, “upper”, “lower”, “front”, “back”, “vertical”, “horizontal”, “top”, “bottom”, “inside”, and “outside”, are used for illustrating positional relationships between constituent elements with reference to the drawings, and are merely for facilitating the description of the specification and simplifying the description, rather than indicating or implying that a referred apparatus or element must have a particular orientation and be constructed and operated in the particular orientation. Therefore, they cannot be understood as limitations on the present disclosure. The positional relationships between the constituent elements may be changed as appropriate according to directions for describing various constituent elements. Therefore, appropriate replacements may be made according to situations without being limited to the wordings described in the specification.

In the specification, unless otherwise specified and defined explicitly, terms “mount”, “mutually connect”, and “connect” should be understood in a broad sense. For example, it may be a fixed connection, or a detachable connection, or an integrated connection. It may be a mechanical connection or an electrical connection. It may be a direct mutual connection, or an indirect connection through middleware, or internal communication between two elements. Those of ordinary skills in the art may understand specific meanings of these terms in the present disclosure according to specific situations.

In the specification, a transistor refers to an element which at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that, in the specification, the channel region refers to a region through which the current mainly flows.

In the specification, a first electrode may be a drain electrode, and a second electrode may be a source electrode. Or, the first electrode may be a source electrode, and the second electrode may be a drain electrode. In a case that transistors with opposite polarities are used, in a case that a direction of a current is changed during operation of a circuit, or the like, functions of the “source electrode” and the “drain electrode” are sometimes interchangeable. Therefore, the “source electrode” and the “drain electrode” are interchangeable and a “source terminal” and a “drain terminal” are interchangeable in the specification.

In the specification, an “electrical connection” includes a case that constituent elements are connected together through an element with a certain electrical effect. The “element with the certain electrical effect” is not particularly limited as long as electrical signals may be sent and received between the connected constituent elements. Examples of the “element with the certain electrical effect” not only include electrodes and wirings, but also include switching elements such as transistors, resistors, inductors, capacitors, and other elements with various functions, etc.

In the specification, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

A triangle, rectangle, trapezoid, pentagon, or hexagon, etc. in the specification is not strictly defined, and may be an approximate triangle, rectangle, trapezoid, pentagon, or hexagon, etc. There may be some small deformation caused by tolerance, and there may be a chamfer, an arc edge, and deformation, etc.

In the present disclosure, “about” refers to that a boundary is not defined so strictly and numerical values within process and measurement error ranges are allowed.

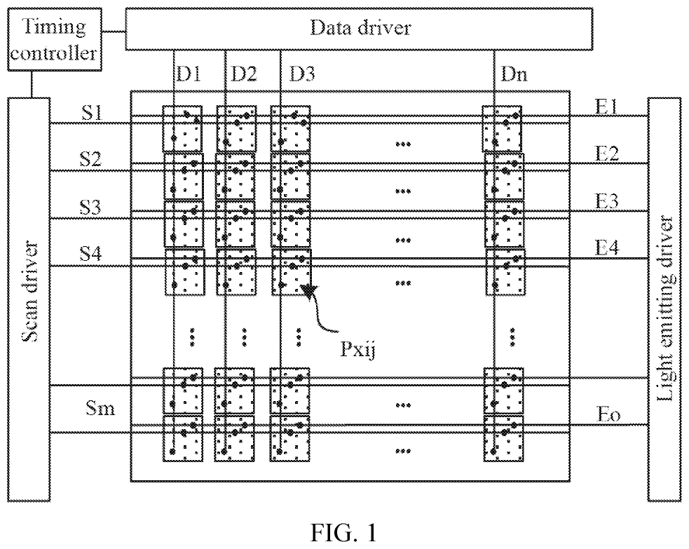

FIG. 1 is a schematic diagram of a structure of a display apparatus. As shown in FIG. 1, the display apparatus may include a timing controller, a data driver, a scan driver, a light emitting driver, and a pixel array, the timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include multiple sub-pixels Pxij, wherein i and j may be natural numbers. At least one sub-pixel Pxij may include a circuit unit and a light emitting unit connected with the circuit unit. The circuit unit may at least include a pixel drive circuit which is connected with a scan signal line, a data signal line, and a light emitting signal line, respectively. In an exemplary implementation mode, the timing controller may provide a grayscale value and a control signal which are suitable for a specification of the data signal driver to the data signal driver, provide a clock signal and a scan start signal, etc. which are suitable for a specification of the scan driver to the scan driver, and provide a clock signal and an emission stop signal, etc. which are suitable for a specification of the light emitting driver to the light emitting driver. The data driver may generate a data voltage to be provided to the data signal lines D1, D2, D3, . . . , and Dn using the grayscale value and the control signal that are received from the timing controller. For example, the data driver may sample the gray-scale value by using the clock signal and apply a data voltage corresponding to the gray-scale value to the data signal lines D1 to Dn by taking a pixel row as a unit, wherein n may be a natural number. The scan driver may generate a scan signal to be provided to the scan signal lines S1, S2, S3, . . . , and Sm by receiving the clock signal and the scan start signal, etc. from the timing controller. For example, the scan signal driver may sequentially provide a scan signal with an on-level pulse to the scan signal lines S1 to Sm. For example, the scan driver may be configured in a form of a shift register and may generate a scan signal in a manner in which a scan start signal provided in a form of an on-level pulse is transmitted to a next-stage circuit sequentially under control of the clock signal, wherein m may be a natural number. The light emitting driver may generate an emission signal to be provided to the light emitting signal lines E1, E2, E3, . . . , and Eo by receiving the clock signal and the emission stop signal, etc., from the timing controller. For example, the light emitting driver may provide an emission signal with an off-level pulse to the light emitting signal lines E1 to Eo sequentially. For example, the light emitting driver may be constructed in a form of a shift register and may generate an emission signal in a manner in which an emission stop signal provided in a form of an off-level pulse is transmitted to a next-stage circuit sequentially under control of the clock signal, wherein o may be a natural number.

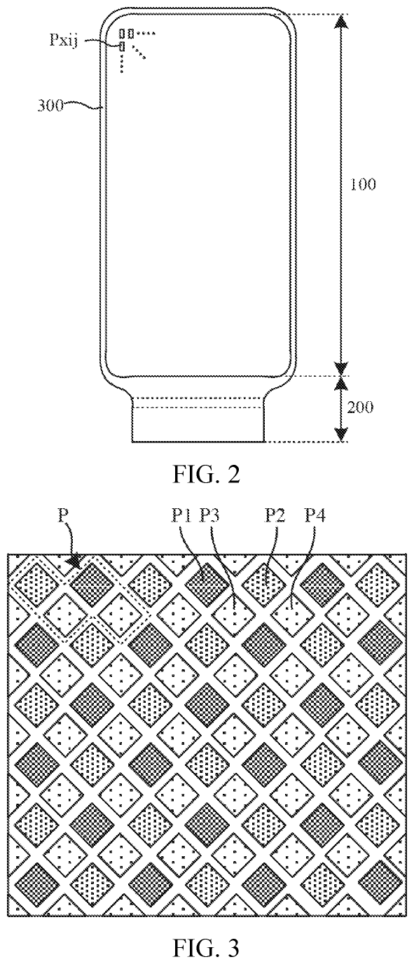

FIG. 2 is a schematic diagram of a structure of a display substrate. As shown in FIG. 2, the display substrate may include a display region 100, a bonding region 200 located on a side of the display region 100, and a bezel region 300 located on another side of the display region 100. In an exemplary implementation mode, the display region 100 may be a plat region including a plurality of sub-pixels Pxij that constitute a pixel array. The plurality of sub-pixels Pxij are configured to display a dynamic picture or a still image, and the display region 100 may be referred to as an Active Area (AA). In an exemplary implementation mode, the display substrate may be a flexible substrate, and accordingly the display substrate may be deformed, for example, may be crimped, bent, folded, or curled.

In an exemplary implementation mode, the bonding region 200 may include a fanout region, a bending region, a drive chip region, and a bonding pin region disposed sequentially along a direction away from the display region, wherein the fanout region may be connected to the display region and includes a plurality of data fanout lines, and a data fanout line is configured to connect a data signal line (Data Line) of the display region in a fanout trace manner. The bending region may be connected to the fanout region, may include a composite insulation layer provided with a groove, and is configured to enable the drive chip region and the bonding pin region to be bent to a back surface of the display region. The driver chip region may be connected to the bending region and may include an Integrated Circuit (IC) configured to be connected with the plurality of data fanout lines. The bonding pin region may be connected to the driver chip region and may include a bonding pad configured to be bound and connected with an external Flexible Printed Circuit (FPC).

In an exemplary implementation mode, the bezel region 300 may include a circuit region, a power supply line region, and a crack dam region, and a cutting region which are sequentially disposed along the direction away from the display region. The circuit region may be connected to the display region and may at least include a gate drive circuit connected with a scan signal line and a light emitting signal line in the display region. The power supply line region may be connected to the circuit region and may at least include a power supply lead line, and the power supply lead line extends along a direction parallel to an edge of the display region and is connected with a cathode in the display region. The crack dam region may be connected to the power supply line region and may at least include multiple cracks disposed on the composite insulation layer. The cutting region may be connected to the crack dam region and may include, at least, a cutting groove disposed on the composite insulation layer, and the cutting groove is configured such that a cutting device cuts along the cutting groove respectively after all film layers of the display substrate are prepared.

In an exemplary implementation mode, the fanout region in the bonding region 200 and the power supply line region in the bezel region 300 may be provided with at least one isolation dam, at least one of which may extend along a direction parallel to the edge of the display region to form an annular structure surrounding the display region, wherein the edge of the display region is an edge on a side of the display region, the bonding region, or the bezel region.

FIG. 3 is a schematic diagram of a planar structure of a display region in a display substrate. As shown in FIG. 3, the display substrate may include a plurality of pixel units P arranged in a matrix. At least one pixel unit P may include a first sub-pixel P1 emitting light of a first color, a second sub-pixel P2 emitting light of a second color, a third sub-pixel P3 and a fourth sub-pixel P4 which emit light of a third color. Each sub-pixel may include a circuit unit and a light emitting unit, wherein the circuit unit may at least include a pixel drive circuit, the pixel drive circuit is connected with a scan signal line, a data signal line, and a light emitting signal line respectively, and the pixel drive circuit is configured to receive a data voltage transmitted by the data signal line and output a corresponding current to the light emitting unit under control of the scan signal line and a light emitting signal line. A light emitting unit in each sub-pixel is connected with a pixel drive circuit of the sub-pixel where the light emitting unit is located, and is configured to emit light with corresponding brightness in response to a current output by the pixel drive circuit of the sub-pixel where the light emitting unit is located.

In an exemplary implementation mode, the first sub-pixel P1 may be a red sub-pixel (R) emitting red light, the second sub-pixel P2 may be a blue sub-pixel (B) emitting blue light, and the third sub-pixel P3 and the fourth sub-pixel P4 may be green sub-pixels (G) emitting green light. In an exemplary implementation mode, a shape of a sub-pixel may be a rectangle, a diamond, a pentagon, or a hexagon. Four sub-pixels may be arranged in a manner of a diamond to form an RGBG pixel arrangement. In another exemplary implementation mode, four sub-pixels may be arranged side by side horizontally, side by side vertically, or in a manner form a square, which is not limited here in the present disclosure.

In an exemplary implementation mode, a pixel unit may include three sub-pixels, and the three sub-pixels may be arranged side by side horizontally, side by side vertically, or in a manner like a Chinese character “nih”, which is not limited here in the present disclosure.

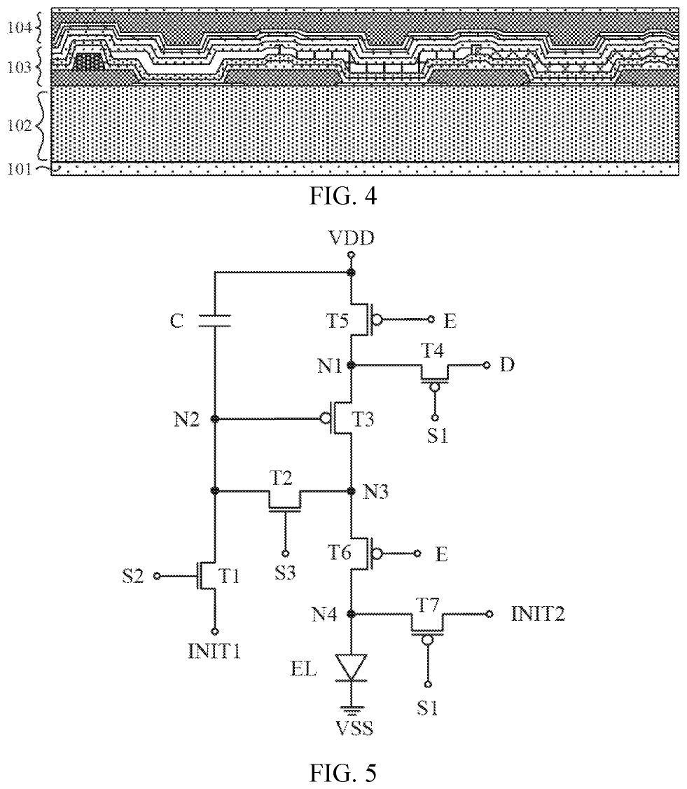

FIG. 4 is a schematic diagram of a sectional structure of a display region in a display substrate, illustrating a structure of four sub-pixels in the display region. As shown in FIG. 4, on a plane perpendicular to the display substrate, the display substrate may include a drive structure layer 102 disposed on a base substrate 101, a light emitting structure layer 103 disposed on a side of the drive structure layer 102 away from the base substrate 101, and an encapsulation structure layer 104 disposed on a side of the light emitting structure layer 103 away from the base substrate 101. In some possible implementation modes, the display substrate may include another film layer, such as a touch structure layer, which is not limited here in the present disclosure.

In an exemplary implementation mode, the base substrate 101 may be a flexible base substrate, or may be a rigid base substrate. The drive structure layer 102 may include a plurality of circuit units, each circuit unit may at least include a pixel drive circuit composed of a plurality of transistors and a storage capacitor. The light emitting structure layer 103 may include a plurality of light emitting units, each light emitting unit may at least include an anode, a pixel definition layer, an organic emitting layer, and a cathode, the anode is connected with the pixel drive circuit, the organic emitting layer is connected with the anode, the cathode is connected with the organic emitting layer, and the organic emitting layer emits light of a corresponding color under drive of the anode and the cathode. The encapsulation layer 104 may include a first encapsulation layer, a second encapsulation layer, and a third encapsulation layer that are stacked, the first encapsulation layer and the third encapsulation layer may be made of an inorganic material, the second encapsulation layer may be made of an organic material, and the second encapsulation layer is disposed between the first encapsulation layer and the third encapsulation layer to form a laminated structure of an inorganic material/an organic material/an inorganic material, which may ensure that external water vapor cannot enter the light emitting structure layer 103.

FIG. 5 is a schematic diagram of an equivalent circuit of a pixel drive circuit. In an exemplary implementation mode, the pixel drive circuit may have a structure of 3T1C, 4T1C, 5T1C, 5T2C, 6T1C, 7T1C, or 8T1C. As shown in FIG. 5, the pixel drive circuit may include seven transistors (a first transistor T1 to a seventh transistor T7) and one storage capacitor C, and the pixel drive circuit is connected with eight signal lines (a first scan signal line S1, a second scan signal line S2, a third scan signal line S3, a light emitting signal line E, a data signal line D, a first initial signal line INIT1, a second initial signal line INIT2, and a first power supply line VDD), respectively.

In an exemplary implementation mode, the pixel drive circuit may include a first node N1, a second node N2, a third node N3, and a fourth node N4. The first node N1 is respectively connected with a first electrode of the third transistor T3, a second electrode of the fourth transistor T4, and a second electrode of the fifth transistor T5, the second node N2 is respectively connected with a second electrode of the first transistor T1, a first electrode of the second transistor T2, a gate electrode of the third transistor T3, and a first end of the storage capacitor C, the third node N3 is respectively connected with a second electrode of the second transistor T2, a second electrode of the third transistor T3, and a first electrode of the sixth transistor T6, the fourth node N4 is respectively connected with a second electrode of the sixth transistor T6 and a second electrode of the seventh transistor T7, and the fourth node N4 is also connected with an anode of a light emitting device EL.

In an exemplary implementation mode, the first end of the storage capacitor C is connected with the second node N2, and a second end of the storage capacitor C is connected with the first power supply line VDD, i.e., the first end of the storage capacitor C is connected with the gate electrode of the third transistor T3.

In an exemplary implementation mode, a gate electrode of the first transistor T1 is connected with the second scan signal line S2, a first electrode of the first transistor T1 is connected with the first initial signal line INIT1, and the second electrode of the first transistor T1 is connected with the second node N2. When a turned-on scan signal is applied to the second scan signal line S2, the first transistor T1 transmits a first initialization voltage to the first end of the storage capacitor C to achieve initialization of the storage capacitor C.

In an exemplary implementation mode, a gate electrode of the second transistor T2 is connected with the third scan signal line S3, the first electrode of the second transistor T2 is connected with the second node N2, and the second electrode of the second transistor T2 is connected with the third node N3. The second transistor T2 enables the gate electrode (the second node N2) of the third transistor T3 to be connected with the second electrode (the third node N3) of the third transistor T3 when a turned-on scan signal is applied to the third scan signal line S3.

In an exemplary implementation mode, the gate electrode of the third transistor T3 is connected with the second node N2, namely the gate electrode of the third transistor T3 is connected with the first end of the storage capacitor C, the first electrode of the third transistor T3 is connected with the first node N1, and the second electrode of the third transistor T3 is connected with the third node N3. The third transistor T3 may be referred to as a drive transistor, and the third transistor T3 determines a size of a drive current flowing between the first power supply line VDD and the light emitting device EL according to a potential difference between the gate electrode and the first electrode of the third transistor T3.

In an exemplary implementation mode, a gate electrode of the fourth transistor T4 is connected with the first scan signal line S1, a first electrode of the fourth transistor T4 is connected with the data signal line D, and the second electrode of the fourth transistor T4 is connected with the first node N1. When a turned-on scan signal is applied to the first scan signal line S1, the fourth transistor T4 enables a data voltage of the data signal line D to be input to the first node N1.

In an exemplary implementation mode, a gate electrode of the fifth transistor T5 is connected with the light emitting signal line E, a first electrode of the fifth transistor T5 is connected with the first power supply line VDD, and the second electrode of the fifth transistor T5 is connected with the first node N1, a signal of the first power supply line VDD is a continuously supplied high-level signal. A gate electrode of the sixth transistor T6 is connected with the emitting signal line E, the first electrode of the sixth transistor T6 is connected with the third node N3, and the second electrode of the sixth transistor T6 is connected with the fourth node N4. When a turned-on light emitting signal is applied to the light emitting signal line E, the fifth transistor T5 and the sixth transistor T6 are turned on, and a drive current path is formed between the first power supply line VDD and the light emitting device EL to enable the light emitting device EL to emit light.

In an exemplary implementation mode, a gate electrode of the seventh transistor T7 is connected with the first scan signal line S1, a first electrode of the seventh transistor T7 is connected with the second initial signal line INIT2, and the second electrode of the seventh transistor T7 is connected with the fourth node N4. When a turned-on scan signal is applied to the first scan signal line S1, the seventh transistor T7 transmits a second initial voltage to the fourth node N4 to initialize or release a charge amount accumulated in the anode of the light emitting device EL.

In an exemplary implementation mode, the light emitting device EL may be an OLED including an anode (first electrode), an organic emitting layer, and a cathode (second electrode) that are stacked, or may be a QLED including an anode (first electrode), a quantum dot emitting layer, and a cathode (second electrode) that are stacked.

In an exemplary implementation mode, the first electrode of the light emitting device EL is connected with the fourth node N4, and the second electrode of the light emitting device EL is connected with a second power supply line VSS, and a signal of the second power supply line VSS is a continuously supplied low-level signal.

In an exemplary implementation mode, the first transistor T1 to the seventh transistor T7 may be P-type transistors or may be N-type transistors. Use of a same type of transistors in a pixel drive circuit may simplify a process flow, reduce a process difficulty of a display panel, and improve a yield of products. In some possible implementation modes, the first transistor T1 to the seventh transistor T7 may include a P-type transistor and an N-type transistor.

In an exemplary implementation mode, for the first transistor T1 to the seventh transistor T7, a low temperature poly silicon transistor may be adopted, or an oxide transistor may be adopted, or a low temperature poly silicon transistor and a metal oxide transistor may be adopted. Low Temperature Poly Silicon (LTPS for short) is adopted for an active layer of a low temperature poly silicon transistor and a metal oxide semiconductor (Oxide) is adopted for an active layer of a metal oxide transistor. A low temperature poly silicon transistor has advantages such as a high migration rate and fast charging, and an oxide transistor has advantages such as a low leakage current. The low temperature poly silicon transistor and the metal oxide transistor are integrated on one display substrate to form a Low Temperature Polycrystalline Oxide (LTPO for short) display substrate, so that advantages of the low temperature poly silicon transistor and the metal oxide transistor may be utilized, low-frequency drive may be achieved, power consumption may be reduced, and display quality may be improved.

In an exemplary implementation mode, a metal oxide transistor may be adopted for the first transistor T1 and the second transistor T2, and a low temperature poly silicon transistor may be adopted for the third transistor T3 to the seventh transistor T7.

In an exemplary implementation mode, taking a case that the first transistor T1 and the second transistor T2 are N-type oxide transistors and the third transistor T3 to the seventh transistor T7 are P-type low temperature poly silicon transistors in the pixel drive circuit shown in FIG. 5 as an example, a working process of the pixel drive circuit may include following stages.

In a first stage (which may be referred to as a reset stage), a signal of the second scan signal line S2 is a turned-on signal (high level), and signals of the first scan signal line S1, the third scan signal line S3, and the light emitting signal line E are turned-off signals. The turned-on signal of the second scan signal line S2 enables the first transistor T1 to be turned on, and a signal of the first initial signal line INIT1 is supplied to the second node N2 through the first transistor T1 to initialize (reset) the storage capacitor C and clear an original charge in the storage capacitor. Since the first end of the storage capacitor C is at a low level, the third transistor T3 is turned on. In this stage, the second transistor T2, the fourth transistor T4, the fifth transistor T5, the sixth transistor T6, and the seventh transistor T7 are turned off, and an OLED does not emit light.

In a second stage (which may be referred to as a data writing stage or a threshold compensation stage), signals of the first scan signal line S1 and the third scan signal line S3 are turned-on signals, signals of the second scan signal line S2 and the light emitting signal line E are turned-off signals, and the data signal line D outputs a data voltage. The turned-on signals of the first scan signal terminal S1 and the third scan signal terminal S3 enable the second transistor T2, the fourth transistor T4, and the seventh transistor T7 to be turned on. The second transistor T2 and the fourth transistor T4 are turned on, so that the data voltage output by the data signal line D is provided to the second node N2 through the first node N1, the turned-on third transistor T3, the third node N3 and the turned-on second transistor T2, and a difference between the data voltage output by the data signal line D and a threshold voltage of the third transistor T3 is charged into the storage capacitor C. A voltage of the first end (the second node N2) of the storage capacitor C is Vd−|Vth|, Vd is the data voltage output by the data signal line D, and Vth is the threshold voltage of the third transistor T3. The seventh transistor T7 is turned on, so that a signal of the second initial signal line INIT2 is provided to a first electrode of the OLED to initialize (reset) the first electrode of the OLED and clear an internal pre-stored voltage therein, thereby completing initialization and ensuring that the OLED does not emit light. In this stage, the first transistor T1, the fifth transistor T5, and the sixth transistor T6 are turned off.

In a third stage (which may be referred to as a light emitting stage), a signal of the light emitting signal line E is a turned-on signal, and signals of the first scan signal line S1, the second scan signal line S2, and the third scan signal line S3 are turned-off signals. The turned-on signal of the light emitting signal line E enables the fifth transistor T5 and the sixth transistor T6 to be turned on, and a power voltage output by the first power supply line VDD provides a drive voltage to the first electrode of the OLED through the turned-on fifth transistor T5, the third transistor T3, and the sixth transistor T6 to drive the OLED to emit light.

In a drive process of the pixel drive circuit, a drive current flowing through the third transistor T3 (drive transistor) is determined by a voltage difference between the gate electrode and the first electrode of the third transistor T3. Since the voltage of the second node N2 is Vd-|Vth|, the drive current of the third transistor T3 is as follows.

$$I = K * {( Vgs - Vth )}^{2} = K * {[ ( Vdd - Vd + \vert Vth \vert ) - Vth ]}^{2} = K * {[ Vdd - Vd ]}^{2}$$

Herein, I is the drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

With development of OLED display technologies, consumers have higher requirements for a display effect of a display product. An extremely narrow bezel has become a new trend in development of display products, so bezel narrowing or even a bezel-less design has been receiving more attention in a design of an OLED display product. In a display substrate, a bonding region generally includes a fanout region, a bending region, a drive chip region, and a bonding pin region disposed sequentially along a direction away from a display region. Since a width of the bonding region is smaller than a width of the display region, signal lines of a drive chip and a bonding pad in the bonding region need to pass through a fanout region to be led into a wider display region in a fanout trace manner, the greater the width difference between the display region and the bonding region, the more oblique fanout lines in a fan-shaped region, the longer the distance between the drive chip region and the display region, so the fan-shaped region occupies a relatively large space, which makes it more difficult to narrow a lower bezel, and the lower bezel is always maintained at about 2.0 mm. In another display substrate, a bezel region is usually provided with a bezel power supply lead line, and the bezel power supply lead line is configured to continuously provide and transmit a low-voltage power supply signal. In order to reduce voltage drop of the low-voltage power supply signals, a width of the bezel power supply lead line is relatively large, resulting in a relatively large width of left and right bezels of a display apparatus.

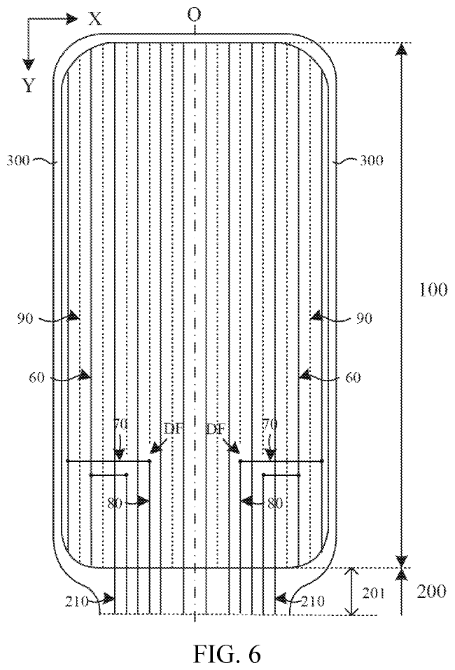

FIG. 6 is a schematic diagram of a planar structure of a display substrate according to an exemplary embodiment of the present disclosure. On a plane perpendicular to the display substrate, the display substrate may include a drive structure layer disposed on a base substrate, a light emitting structure layer disposed on a side of the drive structure layer away from the base substrate, and an encapsulation structure layer disposed on a side of the light emitting structure layer away from the base substrate. As shown in FIG. 6, on a plane parallel to the display substrate, the display substrate may at least include a display region 100, a bonding region 200 located on a side of the display region 100 in a second direction Y, and a bezel region 300 located on another side of the display region 100. In an exemplary implementation mode, the drive structure layer of the display region 100 may include multiple circuit units constituting multiple unit rows and multiple unit columns, and at least one circuit unit may include a pixel drive circuit configured to output a corresponding current to a connected light emitting device. The light emitting structure layer of the display region 100 may include a plurality of light emitting units, at least one light emitting unit may include a light emitting device, the light emitting device is connected with a pixel drive circuit of a corresponding circuit unit, and the light emitting device is configured to emit light with corresponding brightness in response to a current outputted by the connected pixel drive circuit.

In an exemplary implementation mode, the circuit units mentioned in the present disclosure refer to regions divided according to pixel drive circuits, and light emitting units mentioned in the present disclosure refer to regions divided according to light emitting devices. In an exemplary implementation mode, a position and shape of an orthographic projection of a light emitting unit on the base substrate may correspond to a position and shape of an orthographic projection of a circuit unit on the base substrate, or the position and shape of the orthographic projection of the light emitting unit on the base substrate may not correspond to the position and shape of the orthographic projection of the circuit unit on the base substrate.

In an exemplary implementation mode, multiple circuit units sequentially disposed along a first direction X may be referred to as a unit row, and multiple circuit units sequentially disposed along the second direction Y may be referred to as a unit column. Multiple unit rows and multiple unit columns constitute a circuit unit array arranged in an array, and the first direction X and the second direction Y intersect.

In an exemplary implementation mode, the drive structure layer of the display region 100 may further include multiple data signal lines 60, multiple first connection lines 70, and multiple second connection lines 80. The data signal lines 60 are respectively connected with multiple pixel drive circuits in one unit column and are configured to supply data signals to the connected pixel drive circuits. First ends of the plurality of first connection lines 70 are correspondingly connected with the plurality of data signal lines 60, and second ends of the plurality of first connection lines 70 are correspondingly connected with the plurality of second connection lines 80. The first connection lines 70 and the second connection lines 80 constitute data connection lines, a structure in which data connection lines are located in the display region (Fanout in AA, FIAA for short) is formed, and a part of the data signal lines 60 are connected with lead-out lines 210 in the bonding region 200 through data connection lines, while another part of the data signal lines 60 are directly connected with lead-out lines 210 in the bonding region 200.

In an exemplary implementation mode, the bonding region 200 may include a lead region 201, a bending region, a drive chip region, and a bonding pin region which are sequentially disposed along a direction away from the display region, the lead region 201 is connected with the display region 100, and the bending region is connected to the lead region 201. The lead region 201 may be provided with a plurality of lead-out lines 210, the plurality of lead-out lines 210 may extend along the direction away from the display region, first ends of a part of the lead-out lines 210 are correspondingly connected with data signal lines 60 in the display region 100, first ends of another part of the lead lines are correspondingly connected with second connection lines 80 in the display region 100, second ends of the plurality of lead-out lines 210 extend along the second direction Y and cross the bending region, and then are connected with a drive chip of the drive chip region, so that the drive chip applies a data signal provided by the drive chip to the data signal lines 60 through the lead-out lines 210. Since the first connection lines 70 and the second connection lines 80 are disposed in the display region, a length of the lead region along the second direction Y may be effectively reduced, a width of a lower bezel may be greatly reduced, a screen-to-body ratio may be increased, and full-screen display may be achieved.

In an exemplary implementation mode, a lead-out line 210 may be directly connected with a data signal line 60 and a second connection line 80 or may be connected through a via, which is not limited here in the present disclosure.

In an exemplary implementation mode, a first connection line 70 may be in a shape of a line extending along the first direction X, a second connection line 80 may be in a shape of a line extending along the second direction Y, and a data signal line 60 may be in a shape of a line extending along the second direction Y. In an exemplary implementation mode, the first connection line 70 may be disposed perpendicular to the data signal line 60 and the second connection line 80 may be disposed parallel to the data signal line 60.

In the present disclosure, “A extends along a B direction” means that A may include a main portion and a secondary portion connected with the main portion, the main portion is a line, a line segment, or a strip-shaped body, the main portion extends along the B direction, and a length of the main portion extending along the B direction is greater than a length of the secondary portion extending along another direction. In following description, “A extends along a B direction” means “a main body portion of A extends along a B direction”. In an exemplary implementation mode, the second direction Y may be a direction from the display region to the binding region, and an opposite direction of the second direction Y may be a direction from the binding region to the display region.

As shown in FIG. 6, the drive structure layer of the display region 100 may further include a plurality of power supply traces 90. In an exemplary implementation mode, a power supply trace 90 may be in a shape of a line extending along the second direction Y and the plurality of power supply traces 90 may be disposed sequentially along the first direction X.

In an exemplary implementation mode, a power supply trace 90 may be disposed between two data signal lines 60 adjacent in the first direction X.

In an exemplary implementation mode, a power supply trace 90 and a second connection line 80 may be disposed in a same layer and formed synchronously through a same patterning process. At least one circuit column may be provided with only a power supply trace 90 and no second connection line 80 is disposed in the circuit column. At least one circuit column may be provided with a power supply trace 90 and a second connection line 80, and a fracture DF is disposed between the power supply trace 90 and the second connection line 80, and the fracture DF is configured to achieve insulation between the power supply trace 90 and the second connection line 80.

In an exemplary implementation mode, the plurality of power supply traces 90 may be traces that continuously provide low-voltage signals. For example, a power supply trace may be the second power supply line VSS. The plurality of power supply traces 90 may be connected with power supply lead lines disposed in the bonding region or the bezel region. In the present disclosure, a structure in which a low-voltage power supply line is disposed in a sub-pixel (VSS in pixel) is achieved by disposing a power supply trace in the display region, which not only may effectively reduce a resistance of a power supply signal line, effectively reduce voltage drop of a low-voltage power supply signal, and achieve low power consumption, but also may effectively improve uniformity of the power supply signal in the display substrate, effectively improve display uniformity, and improve display attribute and display quality. In addition, the structure in which the low-voltage power supply line is disposed in the sub-pixel may greatly reduce a width of a power supply lead line in the bezel region and the bonding region, which is beneficial to achievement of a narrow bezel.

In an exemplary implementation mode, the display substrate may have a center line O, and the plurality of data signal lines 60, the plurality of first connection lines 70, the plurality of second connection lines 80, the plurality of power supply traces 90, and the plurality of lead-out lines 210 on the display substrate may be symmetrically disposed with respect to the center line O, and the center line O may be a straight line that bisects a plurality of unit columns of the display region 100 and extends along the second direction Y.

In an exemplary implementation mode, the drive structure layer may include a plurality of conductive layers, a first connection line 70 and a second connection line 80 may be disposed in different conductive layers, and a data signal line 60 and a second connection line 80 may be disposed in a same conductive layer, the first connection line 70 may be connected with the data signal line 60 through a first connection hole, and the second connection line 80 may be connected with the first connection line 70 through a second connection hole.

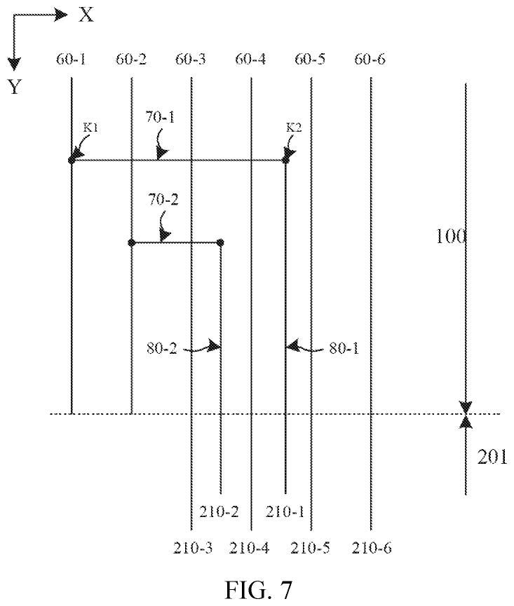

FIG. 7 is a schematic diagram of an arrangement of data connection lines according to an exemplary embodiment of the present disclosure, illustrating a structure of 6 data signal lines, 2 data connection lines, and 6 lead-out lines in a left-side region of a display substrate. As shown in FIG. 7, in an exemplary implementation mode, a plurality of data signal lines in the left-side region may include a data signal line 60-1 to a data signal line 60-6, a plurality of first connection lines may include a first connection line 70-1 and a second connection line 70-2, a plurality of second connection lines 80 may include a second connection line 80-1 and a second connection line 80-2, and a plurality of lead-out lines may include a lead-out line 210-1 to a lead-out line 210-6.

In an exemplary implementation mode, the data signal line 60-1 to the data signal line 60-6 may be in a shape of a line extending along a second direction Y, and may be disposed in order of numbering from small to large along a first direction X. The first connection line 70-1 and the first connection line 70-2 are in a shape of a line extending along the first direction X and may be disposed in order of numbering from small to large along the second direction Y. The second connection line 80-1 and the second connection line 80-2 are in a shape of a line extending along the second direction Y, and may be disposed in order of numbering from large to small along the first direction X.

In an exemplary implementation mode, a first end of the first connection line 70-1 is connected with a data signal line 60-1 through a first connection hole K1, a second end of the first connection line 70-1, after extending along the first direction X, is connected with a first end of the second connection line 80-1 through a second connection hole K2, a second end of the second connection line 80-1, after extending to a bonding region along the second direction Y, is connected with a first end of the lead-out line 210-1, and a second end of the lead-out line 210-1, after extending along the second direction Y and crossing a bending region, is connected with a drive chip of a drive chip region, thereby achieving connection between the lead-out line 210-1 and the data signal line 60-1 through the second connection line 80-1 and the first connection line 70-1.

In an exemplary implementation mode, a first end of the first connection line 70-2 is connected with the data signal line 60-2 through the first connection hole K1, a second end of the first connection line 70-2, after extending along the first direction X, is connected with a first end of the second connection line 80-2 through the second connection hole K2, a second end of the second connection line 80-2, after extending to the bonding region along the second direction Y, is connected with a first end of the lead-out line 210-2, and a second end of the lead-out line 210-2, after extending along the second direction Y and crossing the bending region, is connected with the drive chip of the drive chip region, thereby achieving a connection between the lead-out line 210-2 and the data signal line 60-2 through the second connection line 80-2 and the first connection line 70-2.

In an exemplary implementation mode, the data signal line 60-3 to the data signal line 60-6, after extending to the bonding region along the second direction Y, are correspondingly connected with first ends of the lead-out line 210-3 to the lead-out line 210-6, and second ends of the lead-out line 210-3 to the lead-out line 210-6, after extending along the second direction Y and crossing the bending region, are connected with the drive chip of the drive chip region.

In an exemplary implementation mode, an order of pins connected with lead-out lines in the driver chip is an interleaved order, a second pin (a pin connected with the lead-out line 210-2) is interleaved between a third pin (a pin connected with the lead-out line 210-3) and a fourth pin (a pin connected with the lead-out line 210-4), and a first pin (a pin connected with the lead-out line 210-1) is interleaved between the fourth pin and a fifth pin (a pin connected with the lead-out line 210-5), the driver chip may utilize tan interleaved order design to achieve a data signal output with no sudden change in load, improving display quality. In an exemplary implementation mode, the interleaved order design is only one implementation mode, and an implementation mode of a positive sequence design may be adopted in an actual design. For example, an order of output signals of pins of the drive chip may be consistent with an arrangement order of data signal lines in the display region through an over-line design.

In an exemplary implementation mode, a spacing between adjacent first connection lines 70 in the second direction Y may be the same or different, and a spacing between adjacent second connection lines 80 in the first direction X may be the same or different, and the present disclosure is not limited herein.

In an exemplary implementation mode, at least one second connection line 80 may be disposed between two data signal lines 60 adjacent in the first direction X.

In the present disclosure, a data connection line including a first connection line and a second connection line is disposed in the display region, so that a lead line of the bonding region is connected with a data signal line through the data connection line, so that the lead region does not need to be provided with a fan-shaped oblique line, which effectively reduces a length of the lead region, greatly reduces a width of a lower bezel, increases a screen-to-body ratio, and facilitates achievement of full-screen display.

An exemplary embodiment of the present disclosure provides a display substrate. In an exemplary implementation mode, the display substrate includes a display region including a drive structure layer disposed on a base substrate, the drive structure layer at least includes a plurality of circuit units constituting a plurality of unit rows and a plurality of unit columns, a plurality of data signal lines extending along a second direction, a plurality of first connection lines extending along a first direction, and a plurality of second connection lines extending along a second direction, the first direction intersects with the second direction; a circuit unit includes a pixel drive circuit, at least one data signal line is connected with a plurality of pixel drive circuits of a unit column, first ends of the plurality of first connection lines are correspondingly connected with the plurality of data signal lines, and second ends of the plurality of first connection lines are correspondingly connected with the plurality of second connection lines; pixel drive circuits in adjacent unit columns are mirror symmetrical with respect to a center line, the center line is a straight line located between adjacent unit columns and extending along the second direction, and a second connection line is disposed at a gap between pixel drive circuits of adjacent unit columns.

In an exemplary implementation mode, two data signal lines in at least one adjacent unit column are mirror symmetrical with respect to the second connection line, and a minimum distance between the second connection line and an adjacent data signal line in the first direction is greater than a minimum distance between the two data signal lines in the adjacent unit column in the first direction.

In another exemplary implementation mode, two data signal lines in at least one adjacent unit column are mirror symmetrical with respect to the second connection line, and a minimum distance between the second connection line and an adjacent data signal line in the first direction is ½ of a minimum distance between the two data signal lines in the adjacent unit column in the first direction.

In an exemplary implementation mode, the drive structure layer further includes a plurality of power supply traces extending along the second direction, and the power supply traces are disposed at gaps between pixel drive circuits of adjacent unit columns.

In an exemplary implementation mode, two data signal lines in at least one adjacent unit column are mirror symmetrical with respect to a power supply trace, and a minimum distance between the power supply trace and an adjacent data signal line in the first direction is greater than a minimum distance between the two data signal lines in the adjacent unit column in the first direction.

In another exemplary implementation mode, two data signal lines in at least one adjacent unit column are mirror symmetrical with respect to a power supply trace, and a minimum distance between the power supply trace and an adjacent data signal line in the first direction is ½ of a minimum distance between the two data signal lines in the adjacent unit column in the first direction.

In an exemplary implementation mode, on a plane perpendicular to the display substrate, the drive structure layer includes a plurality of conductive layers sequentially disposed on the base substrate, a first connection line and a second connection line are disposed in different conductive layers, and a data signal line and the second connection line are disposed in a same conductive layer.

In an exemplary implementation mode, the plurality of conductive layers at least include a first source-drain metal layer, a second source-drain metal layer, and a third source-drain metal layer that are sequentially disposed along a direction away from the base substrate, the first connection line is disposed in the second source-drain metal layer, the data signal line and the second connection line are disposed in the third source-drain metal layer, the data signal line is connected with a first end of the first connection line through a via and the second connection line is connected with a second end of the first connection line through a via.

In an exemplary implementation mode, the third source-drain metal layer further includes a plurality of power supply traces extending along the second direction, and the power supply traces are disposed at gaps between pixel drive circuits of adjacent unit columns.

In an exemplary implementation mode, a pixel drive circuit at least includes a storage capacitor and a plurality of transistors, and the plurality of conductive layers include a shielding layer, a first semiconductor layer, a first gate metal layer, a second gate metal layer, a second semiconductor layer, a third gate metal layer, a first source-drain metal layer, a second source-drain metal layer, and a third source-drain metal layer disposed sequentially along a direction away from the base substrate; the shielding layer at least includes a shielding electrode, the first semiconductor layer at least includes active layers of a plurality of low temperature poly silicon transistors, the first gate metal layer at least includes a first scan signal line, a light emitting signal line, and a first electrode plate of the storage capacitor, the second gate metal layer at least includes a second electrode plate of the storage capacitor, the second semiconductor layer at least includes active layers of a plurality of oxide transistors, the third gate metal layer at least includes a second scan signal line and a third scan signal line, the first source-drain metal layer at least includes a second initial signal line of a network communication structure, the second source-drain metal layer at least includes a shielding electrode and the first connection line, and the third source-drain metal layer at least includes a first power supply line, the data signal line, and the second connection line.

In an exemplary implementation mode, the plurality of transistors include a first transistor, a second transistor, a third transistor, a fourth transistor, a fifth transistor, a sixth transistor, and a seventh transistor, the first transistor and the second transistor are oxide transistors, and the third transistor, the fourth transistor, the fifth transistor, the sixth transistor, and the seventh transistor are low temperature poly silicon transistors.

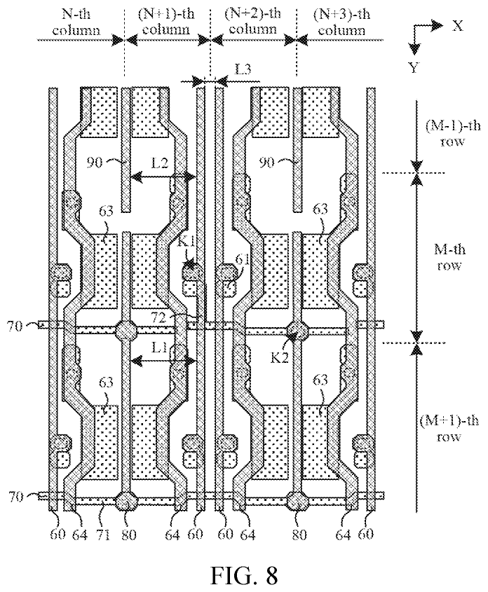

FIG. 8 is a schematic diagram of a planar structure of a display substrate according to an exemplary embodiment of the present disclosure, illustrating a pixel drive circuit structure of eight circuit units (2 unit rows and 4 unit columns) in a display region. In an exemplary implementation mode, the display substrate may include a display region, and the display region may at least include a drive structure layer disposed on a base substrate and a light emitting structure layer disposed on a side of the drive structure layer away from the base substrate. On a plane parallel to the display substrate, the drive structure layer may at least include a plurality of circuit units constituting a plurality of unit rows and a plurality of unit columns, a plurality of circuit units in each unit row are sequentially disposed along a first direction X, the plurality of unit rows are sequentially disposed along a second direction Y, a plurality of circuit units in each unit column are sequentially disposed along the second direction Y, and the plurality of unit columns are sequentially disposed along the first direction X, the first direction X and the second direction Y intersect. In an exemplary implementation mode, the drive structure layer may further include a plurality of data signal lines 60 extending along the second direction Y, a plurality of first connection lines 70 extending along the first direction X, and a plurality of second connection lines 80 extending along the second direction Y. A circuit unit may include a pixel drive circuit, at least one data signal line 60 is electrically connected with a plurality of pixel drive circuits of a unit column, and the data signal line 60 is configured to provide a data signal to the connected pixel drive circuits. In an exemplary implementation mode, first ends of the plurality of first connection lines 70 are correspondingly connected with the plurality of data signal lines 60, and second ends of the plurality of first connection lines 70 are correspondingly connected with the plurality of second connection lines 80, the first connection lines 70 and the second connection lines 80 are configured to provide data signals to the connected data signal lines 60.

In the present disclosure, “A extends along a B direction” means that A may include a main portion and a secondary portion connected with the main portion, the main portion is a line, a line segment, or a strip-shaped body, the main portion extends along the B direction, and a length of the main portion extending along the B direction is greater than a length of the secondary portion extending along another direction. In following description, “A extends along a B direction” means “a main body portion of A extends along a B direction”.

In an exemplary implementation mode, pixel drive circuits in adjacent unit columns may be mirror symmetrical with respect to a center line, the center line may be a straight line located between two adjacent unit columns and extending along the second direction Y, a symmetrical structure enables gaps to be formed between the pixel drive circuits in the adjacent unit columns, and a plurality of second connection lines 80 may be respectively disposed at gaps between the pixel drive circuits in the adjacent unit columns.

In an exemplary implementation mode, at least one second connection line 80 may be disposed between two data signal lines 60 of adjacent unit columns and the two data signal lines 60 may be mirror symmetrical with respect to the second connection line 80.

In an exemplary implementation mode, a minimum distance L1 between at least one second connection line 80 and an adjacent data signal line 60 in the first direction X may be greater than a minimum distance L3 between two data signal lines 60 in adjacent unit columns in the first direction X.

In an exemplary implementation mode, on a plane perpendicular to the display substrate, the drive structure layer may include a first source-drain metal layer, a second source-drain metal layer, and a third source-drain metal layer that are sequentially disposed on the base substrate, the second source-drain metal layer may at least include a first connection line 70, and the third source-drain metal layer may at least include a data signal line 60 and a second connection line 80, that is, the first connection line 70 and the second connection line 80 are disposed in different conductive layers, and the data signal line 60 and the second connection line 80 are disposed in a same conductive layer.

In an exemplary implementation mode, the data signal line 60 may be connected with a first end of the first connection line 70 through a first lap via K1, and the second connection line 80 may be connected with a second end of the first connection line 70 through a second lap via K2, that is, the second connection line 80 extending along the second direction Y and located in the third source-drain metal layer is connected with the first connection line 70 extending along the first direction X and located in the second source-drain metal layer through the first lap via K1, and the first connection line 70 extending along the first direction X and located in the second source-drain metal layer is connected with the data signal line 60 extending along the second direction Y and located in the third source-drain metal layer through the second lap via K2.

In an exemplary implementation mode, the drive structure layer may further include a plurality of power supply traces 90 extending along the second direction Y, and the plurality of power supply traces 90 may be respectively disposed at gaps between pixel drive circuits of adjacent unit columns.

In an exemplary implementation mode, at least one power supply trace 90 may be disposed between two data signal lines 60 of adjacent unit columns, and the two data signal lines 60 may be mirror symmetrical with respect to the power supply trace 90.

In an exemplary implementation mode, a minimum distance L2 between at least one power supply trace 90 and an adjacent data signal line 60 in the first direction X may be greater than a minimum distance L3 between two data signal lines 60 in adjacent unit columns in the first direction X.

In an exemplary implementation mode, the power supply trace 90 may be disposed in the third source-drain metal layer.

In an exemplary implementation mode, a pixel drive circuit may at least include a first transistor, a second transistor, and a storage capacitor, the first transistor at least includes a first active layer, the second transistor at least includes a second active layer, a second region of the first active layer and a first region of the second active layer are interconnected to be of an integral structure, and are connected with a first electrode plate of the storage capacitor through a first connection electrode. At least one circuit unit may further include a shielding electrode 63, an orthographic projection of the shielding electrode 63 on the base substrate is at least partially overlapped with an orthographic projection of the second region of the first active layer and the first region of the second active layer on the base substrate, and the orthographic projection of the shielding electrode 63 on the base substrate is at least partially overlapped with an orthographic projection of the first connection electrode on the base substrate.

In an exemplary implementation mode, at least one circuit unit may further include a first power supply line 64 which may be connected with the shielding electrode 63.

In an exemplary implementation mode, the shielding electrode 63 may be disposed in the second source-drain metal layer, and the first power supply line 64 may be disposed in the third source-drain metal layer, and the first power supply line 64 may be connected with the shielding electrode 63 through a via.

In an exemplary implementation mode, the pixel drive circuit may at least include a fourth transistor, and the data signal line 60 may be connected with a first electrode of the fourth transistor in the pixel drive circuit through a data connection electrode 61. In at least one circuit unit, the first connection line 70 is connected with the data connection electrode 61.

In an exemplary implementation mode, at least one circuit unit may further include a data connection block 72, a first end of the data connection block 72 is connected with the first connection line 70, and a second end of the data connection block 72 is connected with the data connection electrode 61.

In an exemplary implementation mode, the first connection line 70, the data connection block 72, and the data connection electrode 61 are disposed in a same layer and are interconnected to be of an integral structure.

In an exemplary implementation mode, the plurality of transistors may include a first transistor, a second transistor, a third transistor, a fourth transistor, a fifth transistor, a sixth transistor, and a seventh transistor, the first transistor and the second transistor are oxide transistors, and the third transistor, the fourth transistor, the fifth transistor, the sixth transistor, and the seventh transistor are low temperature poly silicon transistors.

In an exemplary implementation mode, the pixel drive circuit at least includes a storage capacitor and a plurality of transistors, and the plurality of conductive layers may include a shielding layer, a first semiconductor layer, a first gate metal layer, a second gate metal layer, a second semiconductor layer, a third gate metal layer, a first source-drain metal layer, a second source-drain metal layer, and a third source-drain metal layer that are sequentially disposed along a direction away from the base substrate. The shielding layer may at least include a shielding electrode, the first semiconductor layer may at least include active layers of a plurality of low temperature poly silicon transistors, the first gate metal layer may at least include a first scan signal line, a light emitting signal line, and a first electrode plate of the storage capacitor, the second gate metal layer may at least include a second electrode plate of the storage capacitor, the second semiconductor layer may at least include active layers of a plurality of oxide transistors, the third gate metal layer may at least include a second scan signal line and a third scan signal line, the first source-drain metal layer may at least include a second initial signal line of a network communication structure, the second source-drain metal layer may at least include a shielding electrode and a first connection line, and the third source-drain metal layer may at least include a first power supply line, a data signal line, and a second connection line.

Exemplary description is made below through a preparation process of a display substrate. A “patterning process” mentioned in the present disclosure includes photoresist coating, mask exposure, development, etching, and photoresist stripping, etc. for a metal material, an inorganic material, or a transparent conductive material, and includes organic material coating, mask exposure, and development, etc. for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or another process. If the “thin film” does not need a patterning process in an entire manufacturing process, the “thin film” may also be called a “layer”. If the “thin film” needs the patterning process in the entire manufacturing process, the “thin film” is called a “thin film” before the patterning process and is called a “layer” after the patterning process. The “layer” after the patterning process contains at least one “pattern”. “A and B are disposed in a same layer” mentioned in the present disclosure means that A and B are formed simultaneously through a same patterning process, and a “thickness” of a film layer is a size of the film layer in a direction perpendicular to the display substrate. In an exemplary implementation of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A is overlapped with the boundary of the orthographic projection of B.

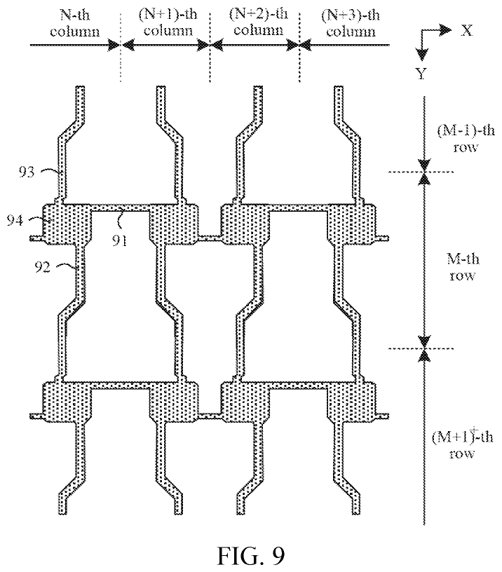

In an exemplary implementation mode, taking eight circuit units (2 unit rows and 4 unit columns) as an example, a preparation process of a drive structure layer may include following operations.
(1) A pattern of a shielding layer is formed. In an exemplary implementation mode, forming a pattern of a shielding layer may include: depositing a shielding thin film on a base substrate, patterning the shielding thin film through a patterning process to form a pattern of a shielding layer on the base substrate, as shown in FIG. 9.

In an exemplary implementation mode, a pattern of a shielding layer of each circuit unit may at least include a first shielding connection line 91, a second shielding connection line 92, a third shielding connection line 93, and a shielding electrode 94.

In an exemplary implementation mode, the shielding electrode 94 may be in a shape of a rectangle, corners of the rectangle may be provided with chamfers. The first shielding connection line 91 may be in a shape of a straight line extending along a first direction X, and the first shielding connection line 91 may be disposed on a side of the shielding electrode 94 in the first direction X and connected with the shielding electrode 94. The second shielding connection line 92 may be in a shape of a fold line extending along a second direction Y, and the second shielding connection line 92 may be disposed on a side of the shielding electrode 94 in the second direction Y and connected with the shielding electrode 94. The third shielding connection line 93 may be in a shape of a fold line extending along the second direction Y, and the third shielding connection line 93 may be disposed on a side of the shielding electrode 94 in an opposite direction of the second direction Y and connected with the shielding electrode 94.

In an exemplary implementation mode, the first shielding connection line 91 of each circuit unit is connected with a shielding electrode 94 of an adjacent circuit unit in the first direction X, so that shielding layers in one unit row are connected into a whole to form an interconnected integral structure.

In an exemplary implementation mode, the second shielding connection line 92 of each circuit unit is connected with a third shielding connection line 93 of an adjacent circuit unit in the second direction Y, so that shielding layers in one unit column are connected into a whole to form an interconnected integral structure.

In an exemplary implementation mode, shielding layers in a unit row and a unit column are connected into a whole, which may ensure that the shielding layers in the display substrate have a same potential, which is beneficial to improving uniformity of a panel, avoiding poor display of the display substrate, and ensuring a display effect of the display substrate.

In an exemplary implementation mode, shielding layers of adjacent unit columns may be mirror symmetrical with respect to a center line which may be a straight line located between adjacent unit columns and extending along the second direction Y. For example, a shielding layer of an N-th column and a shielding layer of an (N+1)-th column may be mirror symmetrical with respect to the center line, the shielding layer of the (N+1)-th column and a shielding layer of an (N+2)-th column may be mirror symmetrical with respect to the center line, and the shielding layer of the (N+2)-th column and a shielding layer of an (N+3)-th column may be mirror symmetrical with respect to the center line.

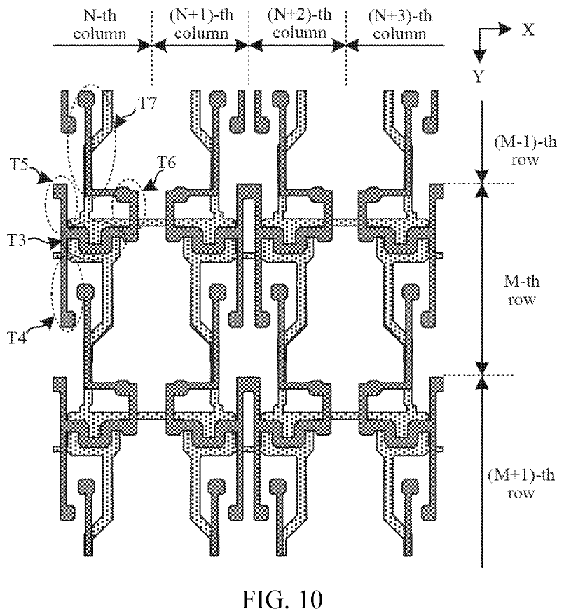

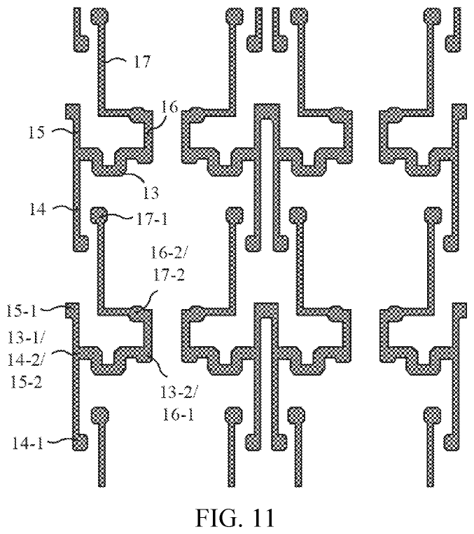

In an exemplary implementation mode, shapes of shielding layers in a plurality of unit rows may be substantially the same.
(2) A pattern of a first semiconductor layer is formed. In an exemplary implementation mode, forming a pattern of a first semiconductor may include: sequentially depositing a first insulation thin film and a first semiconductor thin film on the base substrate, patterning the first semiconductor thin film through a patterning process to form a first insulation layer covering the shielding layer, and a pattern of a first semiconductor disposed on the first insulation layer, as shown in FIG. 10 and FIG. 11, and FIG. 11 is a schematic plan view of the first semiconductor layer in FIG. 10.

In an exemplary implementation mode, a pattern of a first semiconductor layer of each circuit unit may at least include a third active layer 13 of a third transistor T3 to a seventh active layer 17 of a seventh transistor T7, and the third active layer 13 to the seventh active layer 17 are of an interconnected integral structure.

In an exemplary implementation mode, an orthographic projection of the third active layer 13 on the base substrate is at least partially overlapped with an orthographic projection of the shielding electrode 94 on the base substrate. In the first direction X, the sixth active layer 16 may be located on a side of the third active layer 13 in the present circuit unit in the first direction X, and the fourth active layer 14 and the fifth active layer 15 may be located on a side of the third active layer 13 in the present circuit unit in an opposite direction of the first direction X. In the second direction Y, the fourth active layer 14 in a circuit unit of an M-th row may be located on a side of the third active layer 13 in the present circuit unit close to a circuit unit of an (M+1)-th row, and the fifth active layer 15, the sixth active layer 16, and the seventh active layer 17 in the circuit unit of the M-th row may be located on a side of the third active layer 13 in the present circuit unit away from the circuit unit of the (M+1)-th row, and M may be a positive integer greater than or equal to 1.

In an exemplary implementation mode, the third active layer 13 may have a shape of an inverted “Ω”, the fourth active layer 14 and the fifth active layer 15 may have a shape of an “I”, and the sixth active layer 16 and the seventh active layer 17 may have a shape of an “L”.

In an exemplary implementation mode, the third active layer 13 to the seventh active layer 17 may each include a first region, a second region, and a channel region located between the first region and the second region. In an exemplary implementation mode, a first region 13-1 of the third active layer may simultaneously serve as a second region 14-2 of the fourth active layer and a second region 15-2 of the fifth active layer, a second region 13-2 of the third active layer may simultaneously serve as a first region 16-1 of the sixth active layer, a second region 16-2 of the sixth active layer may simultaneously serve as a second region 17-2 of the seventh active layer, and a first region 14-1 of the fourth active layer, a first region 15-1 of the fifth active layer, and a first region 17-1 of the seventh active layer may be individually disposed.

In an exemplary implementation mode, a first region 17-1 of a seventh active layer in the circuit unit of the (M+1)-th row may be disposed in the circuit unit of the M-th row.

In an exemplary implementation mode, in one unit row, first regions 15-1 of fifth active layers of two partially adjacent circuit units may be connected with each other. For example, a first region 15-1 of a fifth active layer of an (N+1)-th column and a first region 15-1 of a fifth active layer of an (N+2)-th column are connected with each other. Since a first region of a fifth active layer in each circuit unit is configured to be connected with a first power supply line formed subsequently, by setting first regions of fifth active layers of adjacent circuit units to be interconnected to be of an integral structure, first electrodes of fifth transistors T5 of the adjacent circuit units may be guaranteed to have a same potential, which is beneficial for improving uniformity of a panel, avoiding poor display of the display substrate, and ensuring a display effect of the display substrate.

In an exemplary implementation mode, first semiconductor layers of adjacent unit columns may be mirror symmetrical with respect to a center line. For example, a first semiconductor layer of an N-th column and a first semiconductor layer of an (N+1)-th column may be mirror symmetrical with respect to a center line, the first semiconductor layer of the (N+1)-th column and a first semiconductor layer of an (N+2)-th column may be mirror symmetrical with respect to a center line, and the first semiconductor layer of the (N+2)-th column and a first semiconductor layer of an (N+3)-th column may be mirror symmetrical with respect to a center line. In an exemplary implementation mode, shapes of first semiconductor layers in a plurality of unit rows may be substantially the same.

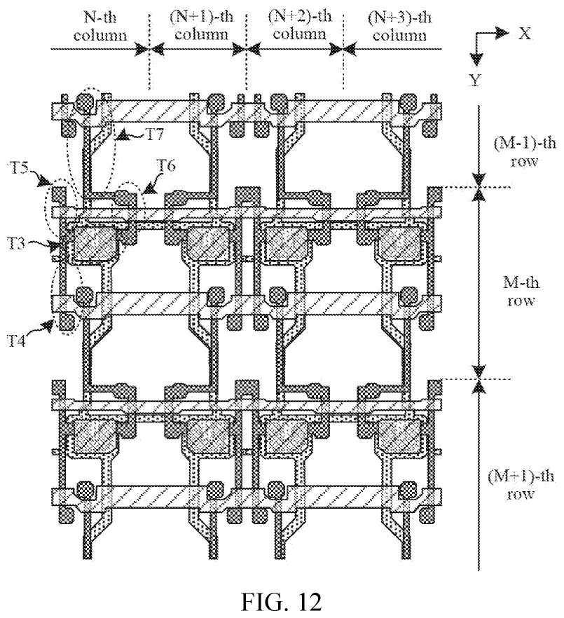

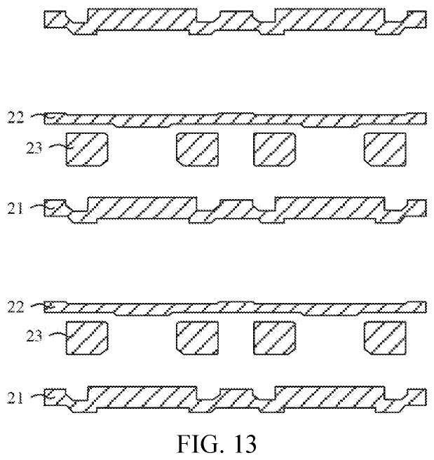

In an exemplary implementation mode, the first semiconductor layer may be made of poly Silicon (p-Si), i.e., the third transistor to the seventh transistor are LTPS transistors. In an exemplary implementation mode, the patterning the first semiconductor thin film through the patterning process may include: forming an amorphous silicon (a-si) thin film on the first insulation thin film, dehydrogenating the amorphous silicon thin film, and crystallizing the dehydrogenated amorphous silicon thin film to form a poly silicon thin film. Subsequently, the poly silicon thin film is patterned to form the pattern of the first semiconductor layer.
(3) A pattern of a first conductive layer is formed. In an exemplary implementation mode, forming a pattern of a first conductive layer may include: sequentially depositing a second insulation thin film and a first conductive thin film on the base substrate on which the above-mentioned patterns are formed, and patterning the first conductive thin film through a patterning process to form a second insulation layer that covers the pattern of the first semiconductor layer and form a pattern of a first conductive layer disposed on the second insulation layer, as shown in FIG. 12 and FIG. 13, and FIG. 13 is a schematic plan view of the first conductive layer in FIG. 12. In an exemplary implementation mode, the first conductive layer may be referred to as a first gate metal (GATE1) layer.

In an exemplary implementation mode, a pattern of a first conductive layer of each circuit unit at least includes a first scan signal line 21, a light emitting signal line 22, and a first electrode plate 23 of a storage capacitor.

In an exemplary implementation mode, the first electrode plate 23 may be in a shape of a rectangle, corners of the rectangle may be provided with chamfers, and an orthographic projection of the first electrode plate 23 on the base substrate is at least partially overlapped with an orthographic projection of the third active layer of the third transistor T3 on the base substrate. In an exemplary implementation mode, the first electrode plate 23 may simultaneously serve as one electrode plate of the storage capacitor and a gate electrode of the third transistor T3.

In an exemplary implementation mode, the first scan signal line 21 may be in a shape of a line with a main body portion extending along the first direction X, a first scan signal line 21 in the circuit unit of the M-th row may be located on a side of the first electrode plate 23 of the present circuit unit close to the circuit unit of the (M+1)-th row, a region where the first scan signal line 21 in the circuit unit of the M-th row is overlapped with a fourth active layer of the present circuit unit serves as a gate electrode of the fourth transistor T4, and a region where the first scan signal line 21 in the circuit unit of the M-th row is overlapped with a seventh active layer in the circuit unit of the (M+1)-th row serves as a gate electrode of the seventh transistor T7.

In an exemplary implementation mode, the light emitting signal line 22 may be in a shape of a line with a main body portion extending along the first direction X, a light emitting signal line 22 in the circuit unit of the M-th row may be located on a side of the first electrode plate 23 of the present circuit unit away from the circuit unit of the (M+1)-th row, a region where the light emitting signal line 22 is overlapped with a fifth active layer of the present circuit unit serves as a gate electrode of the fifth transistor T5, and a region where the light emitting signal line 22 is overlapped with a sixth active layer of the present circuit unit serves as a gate electrode of the sixth transistor T6.

In an exemplary embodiment, the first scan signal line 21 and the light emitting signal line 22 may be designed with unequal widths, and widths of the first scan signal line 21 and the light emitting signal line 22 are dimensions in the second direction Y, so that not only a layout of a pixel structure may be facilitated, but also a parasitic capacitance between signal lines may be reduced, which is not limited here in the present disclosure.

In an exemplary implementation mode, the first scan signal line 21 may include a region overlapping with the first semiconductor layer and a region not overlapping with the first semiconductor layer, and a width of the first scan signal line 21 in the region overlapping with the first semiconductor layer may be less than a width of the first scan signal line 21 in the region not overlapping with the first semiconductor layer.

In an exemplary implementation mode, the light emitting signal line 22 may include a region overlapping with the first semiconductor layer and a region not overlapping with the first semiconductor layer, and a width of the first scan signal line 21 in the region overlapping with the first semiconductor layer may be greater than a width of the first scan signal line 21 in the region not overlapping with the first semiconductor layer.

In an exemplary implementation mode, first conductive layers of adjacent unit columns may be mirror symmetrical with respect to a center line. For example, a first conductive layer of an N-th column and a first conductive layer of an (N+1)-th column may be mirror symmetrical with respect to a center line, the first conductive layer of the (N+1)-th column and a first conductive layer of an (N+2)-th column may be mirror symmetrical with respect to a center line, and the first conductive layer of the (N+2)-th column and a first conductive layer of an (N+3)-th column may be mirror symmetrical with respect to a center line. In an exemplary implementation mode, shapes of first conductive layers in a plurality of unit rows may be substantially the same.

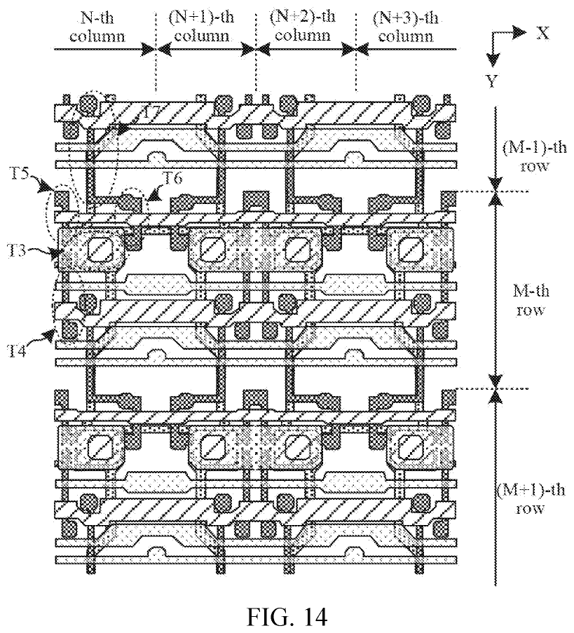

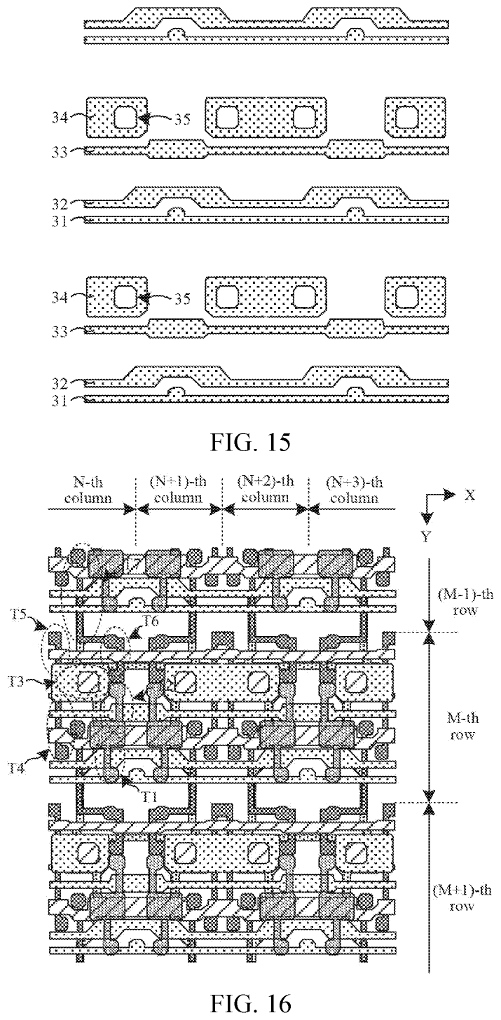

In an exemplary implementation mode, after the pattern of the first conductive layer is formed, the first semiconductor layer may be subjected to a conductive treatment by using the first conductive layer as a shield. The first semiconductor layer in a region shielded by the first conductive layer, forms channel regions of the third transistor T3 to the seventh transistor T7, and the first semiconductor layer in a region not shielded by the first conductive layer, is made to be conductive, that is, first regions and second regions of the third transistor T3 to the seventh active layer are all made to be conductive.
(4) A pattern of a second conductive layer is formed. In an exemplary implementation mode, forming a pattern of a second conductive layer may include: depositing a third insulation thin film and a second conductive thin film sequentially on the base substrate on which the aforementioned patterns are formed, and patterning the second conductive thin film using a patterning process to form a third insulation layer covering the first conductive layer and a pattern of a second conductive layer disposed on the third insulation layer, as shown in FIG. 14 and FIG. 15, and FIG. 15 is a schematic plan view of the second conductive layer in FIG. 14. In an exemplary implementation mode, the second conductive layer may be referred to as a second gate metal (GATE2) layer.

In an exemplary implementation mode, a pattern of a second conductive layer of each circuit unit at least includes a first initial signal line 31, a second shielding line 32, a third shielding line 33, and a second electrode plate 34 of the storage capacitor.

In an exemplary implementation mode, a profile of the second electrode plate 34 may be in a shape of a rectangle, and corners of the rectangle may be provided with chamfers. An orthographic projection of the second electrode plate 34 on the base substrate is at least partially overlapped with an orthographic projection of the first electrode plate 23 on the base substrate. The second electrode plate 34 may serve as the other electrode plate of the storage capacitor, the first electrode plate 23 and the second electrode plate 34 constitute the storage capacitor of a pixel drive circuit.

In an exemplary implementation mode, the second electrode plate 34 is provided with an opening 35 which may have a rectangular shape and may be located in a middle of the second electrode plate 34, so that the second electrode plate 34 forms an annular structure. The opening 35 exposes the third insulation layer covering the first electrode plate 23, and an orthographic projection of the first electrode plate 23 on the base substrate contains an orthographic projection of the opening 35 on the base substrate. In an exemplary implementation mode, the opening 35 is configured to accommodate a first via subsequently formed, wherein the first via is located within the opening 35 and exposes the first electrode plate 23, so that a second electrode of the first transistor T1 subsequently formed is connected with the first electrode plate 23.

In an exemplary implementation mode, part of second electrode plates 34 in two adjacent circuit units in a unit row may be connected with each other. For example, a second electrode plate 34 of an (N+1)-th column and a second electrode plate 34 of an (N+2)-th column are of an interconnected integral structure. In an exemplary implementation mode, since the second electrode plate 34 in each circuit unit is connected with the first power supply line formed subsequently, by forming second electrode plates 34 in adjacent circuit units into an interconnected integral structure, the second electrode plates in the integral structure may be reused as power supply signal lines, so that a plurality of second electrode plates in one unit row may be guaranteed to have a same potential, which is beneficial to improving uniformity of a panel and avoiding poor display of the display substrate, thereby ensuring a display effect of the display substrate.

In an exemplary implementation mode, the first initial signal line 31 may be in a shape of a line with a main body portion extending along the first direction X, and a first initial signal line 31 in the circuit unit of the M-th row may be located on a side of the second electrode plate 34 of the present circuit unit close to the circuit unit of the (M+1)-th row.

In an exemplary implementation mode, the second shielding line 32 and the third shielding line 33 may be in a shape of a line with a main body portion extending along the first direction X, a second shielding line 32 and a third shielding line 33 in the circuit unit of the M-th row may be located between the first initial signal line 31 and the second electrode plate 34 of the present circuit unit, and the second shielding line 32 may be located on a side of the third shielding line 33 away from the second electrode plate 34, that is, the third shielding line 33 may be located between the second shielding line 32 and the second electrode plate 34.

In an exemplary implementation mode, the second shielding line 32 is configured to shield a first active layer of the first transistor, and the third shielding line 33 is configured to shield a second active layer of the second transistor. The second shielding line 32 and the third shielding line 33 may be designed with unequal widths, and widths of the second shielding line 32 and the third shielding line 33 are dimensions in the second direction Y, so that not only a layout of a pixel structure may be facilitated, but also a parasitic capacitance between signal lines may be reduced, which is not limited here in the present disclosure.

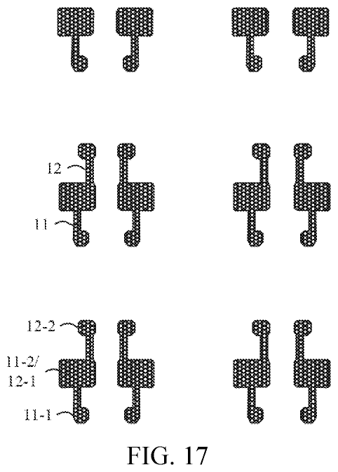

In an exemplary implementation mode, second conductive layers of adjacent unit columns may be mirror symmetrical with respect to a center line. For example, a second conductive layer of the N-th column and a second conductive layer of the (N+1)-th column may be mirror symmetrical with respect to a center line, the second conductive layer of the (N+1)-th column and a second conductive layer of the (N+2)-th column may be mirror symmetrical with respect to a center line, and the second conductive layer of the (N+2)-th column and a second conductive layer of the (N+3)-th column may be mirror symmetrical with respect to a center line. In an exemplary implementation mode, shapes of second conductive layers in a plurality of unit rows may be substantially the same.
(5) A pattern of a second semiconductor layer is formed. In an exemplary implementation mode, forming a pattern of a second semiconductor layer may include: depositing a fourth insulation thin film and a second semiconductor thin film sequentially on the base substrate on which the aforementioned patterns are formed, and patterning the second semiconductor thin film through a patterning process to form a fourth insulation layer covering the base substrate and a pattern of a second semiconductor layer disposed on the fourth insulation layer, as shown in FIG. 16 and FIG. 17, and FIG. 17 is a schematic plan view of the second semiconductor layer in FIG. 16.

In an exemplary implementation mode, a pattern of a second semiconductor layer of each circuit unit at least includes a first active layer 11 of the first transistor T1 and a second active layer 12 of the second transistor T2.

In an exemplary implementation mode, the first active layer 11 and the second active layer 12 may have a shape of an “I”, and a first active layer 11 in the circuit unit of the M-th row may be located on a side of the second active layer 12 of the present circuit unit close to the circuit unit of the (M+1)-th row.

In an exemplary implementation mode, an orthographic projection of the first active layer 11 on the base substrate is at least partially overlapped with an orthographic projection of the second shielding line 32 on the base substrate, and an orthographic projection of the second active layer 12 on the base substrate is at least partially overlapped with an orthographic projection of the third shielding line 33 on the base substrate.

In an exemplary implementation mode, the first active layer 11 and the second active layer 12 may each include a first region, a second region, and a channel region located between the first region and the second region. A first region 11-1 of the first active layer may be located on a side of the second shielding line 32 away from the second active layer 12, and a second region 11-2 of the first active layer may be located on a side of the second shielding line 32 close to the second active layer 12. A first region 12-1 of the second active layer may be located on a side of the third shielding line 33 away from the first active layer 11, and a second region 12-2 of the second active layer may be located on a side of the third shielding line 33 close to the first active layer 11.

In an exemplary implementation mode, the second region 11-2 of the first active layer may serve as the first region 12-1 of the second active layer, that is, the second region 11-2 of the first active layer and the first region 12-1 of the second active layer are of an interconnected integral structure and may be located between the second shielding line 32 and the third shielding line 33.

In an exemplary implementation mode, an orthographic projection of the second region 11-2 of the first active layer and the first region 12-1 of the second active layer in the integral structure on the base substrate is at least partially overlapped with an orthographic projection of the first scan signal line 21 in the present circuit unit on the base substrate.

In an exemplary implementation mode, second semiconductor layers of adjacent unit columns may be mirror symmetrical with respect to a center line. For example, a second semiconductor layer of the N-th column and a second semiconductor layer of the (N+1)-th column may be mirror symmetrical with respect to a center line, the second semiconductor layer of the (N+1)-th column and a second semiconductor layer of the (N+2)-th column may be mirror symmetrical with respect to a center line, and the second semiconductor layer of the (N+2)-th column and a second semiconductor layer of the (N+3)-th column may be mirror symmetrical with respect to a center line. In an exemplary implementation mode, shapes of second semiconductor layers in a plurality of unit rows may be substantially the same.

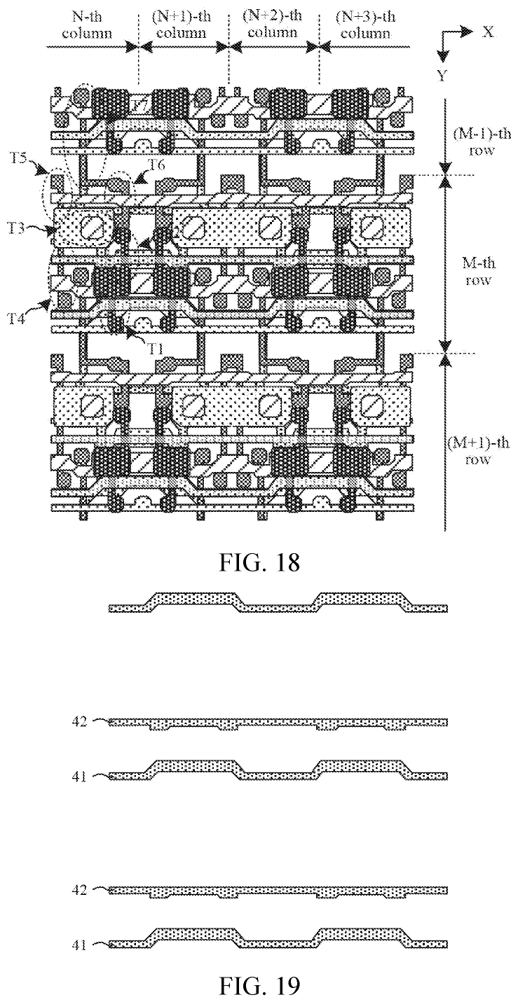

In an exemplary implementation mode, the second semiconductor layer may be made of an oxide, that is, the first transistor T1 and the second transistor T2 are oxide transistors. In an exemplary implementation mode, the second semiconductor thin film may be made of Indium Gallium Zinc Oxide (IGZO), wherein an electron mobility of the Indium Gallium Zinc Oxide (IGZO) is higher than that of amorphous silicon.
(6) A pattern of a third conductive layer is formed. In an exemplary implementation mode, forming a pattern of a third conductive layer may include: depositing a fifth insulation thin film and a third conductive thin film sequentially on the base substrate on which the aforementioned patterns are formed, and patterning the third conductive thin film using a patterning process to form a fifth insulation layer covering the second semiconductor layer and a pattern of a third conductive layer disposed on the fifth insulation layer, as shown in FIG. 18 and FIG. 19, FIG. 19 is a schematic plan view of the third conductive layer in FIG. 18. In an exemplary implementation mode, the second conductive layer may be referred to as a third gate metal (GATE3) layer.

In an exemplary implementation mode, a pattern of a third conductive layer of each circuit unit at least includes a second scan signal line 41 and a third scan signal line 42.

In an exemplary implementation mode, the second scan signal line 41 and the third scan signal line 42 may be in a shape of a line with a main body portion extending along the first direction X, a second scan signal line 41 and a third scan signal line 42 in the circuit unit of the M-th row may be located between the first initial signal line 31 and the second electrode plate 34 of the present circuit unit, and the second scan signal line 41 may be located on a side of the third scan signal line 42 away from the second electrode plate 34, that is, the third scan signal line 42 may be located between the second scan signal line 41 and the second electrode plate 34.

In an exemplary embodiment, a region where the second scan signal line 41 is overlapped with the first active layer serves as a gate electrode of the first transistor T1, and a region where the third scan signal line 42 is overlapped with the second active layer serves as a gate electrode of the second transistor T2.

In an exemplary embodiment, an orthographic projection of the second scan signal line 41 on the base substrate is at least partially overlapped with an orthographic projection of the second shielding line 32 on the base substrate, and the second shielding line 32 and the second scan signal line 41 may be connected with a same signal source, so that the second shielding line 32 may serve as a bottom gate electrode of the first transistor T1 and the second scan signal line 41 may serve as a top gate electrode of the first transistor T1 to form the first transistor T1 with a double gate structure.

In an exemplary embodiment, an orthographic projection of the third scan signal line 42 on the base substrate is at least partially overlapped with an orthographic projection of the third shielding line 33 on the base substrate, and the third shielding line 33 and the third scan signal line 42 may be connected with a same signal source, so that the third shielding line 33 may serve as a bottom gate electrode of the second transistor T2 and the third scan signal line 42 may serve as a top gate electrode of the second transistor T2 to form the second transistor T2 with a double gate structure.

In an exemplary implementation mode, third conductive layers of adjacent unit columns may be mirror symmetrical with respect to a center line. For example, a third conductive layer of the N-th column and a third conductive layer of the (N+1)-th column may be mirror symmetrical with respect to a center line, the third conductive layer of the (N+1)-th column and a third conductive layer of the (N+2)-th column may be mirror symmetrical with respect to a center line, and the third conductive layer of the (N+2)-th column and a third conductive layer of the (N+3)-th column may be mirror symmetrical with respect to a center line. In an exemplary implementation mode, shapes of third conductive layers in a plurality of unit rows may be substantially the same.

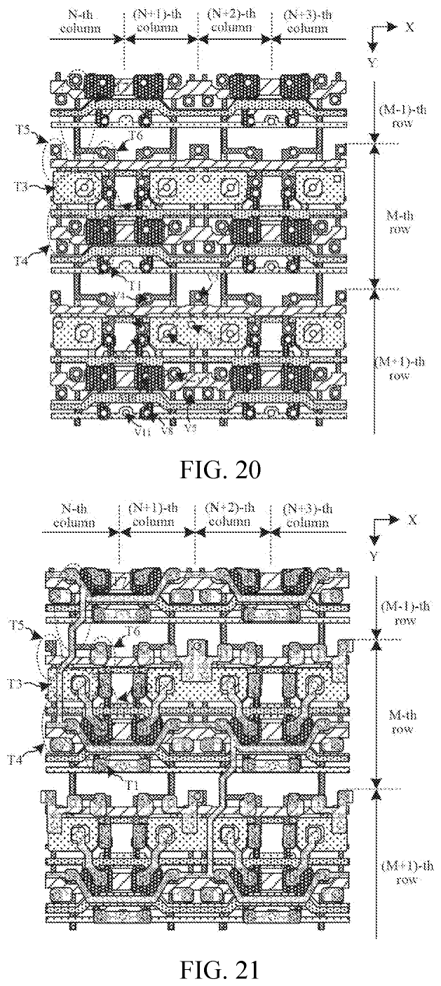

(7) A pattern of a sixth insulation layer is formed. In an exemplary implementation mode, forming a pattern of a sixth insulation layer may include: depositing a sixth insulation thin film on the base substrate on which the aforementioned patterns are formed, patterning the sixth insulation thin film using a patterning process to form a sixth insulation layer covering the third conductive layer, and a plurality of vias are provided on the sixth insulation layer, as shown in FIG. 20.

In an exemplary implementation mode, a plurality of vias of each circuit unit at least include a first via V1, a second via V2, a third via V3, a fourth via V4, a fifth via V5, a sixth via V6, a seventh via V7, an eighth via V8, a ninth via V9, a tenth via V10, and an eleventh via V11.

In an exemplary implementation mode, the orthographic projection of the first via V1 on the base substrate is within a range of the orthographic projection of the opening 35 on the base substrate, the sixth insulation layer, the fifth insulation layer, the fourth insulation layer, and the third insulation layer within the first via V1 are etched away so as to expose a surface of the first electrode plate 23. The first via V1 is configured such that a first connection electrode formed subsequently is connected with the first electrode plate 23 through the via.

In an exemplary implementation mode, an orthographic projection of the second via V2 on the base substrate is within a range of the orthographic projection of the second electrode plate 34 on the base substrate, the sixth insulation layer, the fifth insulation layer, and the fourth insulation layer within the second via V2 are etched away to expose a surface of the second electrode plate 34, and the second via V2 is configured such that a fourth connection electrode formed subsequently is connected with the second electrode plate 34 through the via.

In an exemplary implementation mode, an orthographic projection of the third via V3 on the base substrate is within a range of an orthographic projection of the first region of the fifth active layer on the base substrate, the sixth insulation layer, the fifth insulation layer, the fourth insulation layer, the third insulation layer, and the second insulation layer within the third via V3 are etched away to expose a surface of the first region of the fifth active layer, and the third via V3 is configured such that the fourth connection electrode subsequently formed is connected with the first region of the fifth active layer through the via.

In an exemplary implementation mode, an orthographic projection of the fourth via V4 on the base substrate is within a range of an orthographic projection of the second region of the sixth active layer (which is also the second region of the seventh active layer) on the base substrate, the sixth insulation layer, the fifth insulation layer, the fourth insulation layer, the third insulation layer, and the second insulation layer within the fourth via V4 are etched away to expose a surface of the second region of the sixth active layer (which is also the second region of the seventh active layer), and the fourth via V4 is configured such that a sixth connection electrode subsequently formed is connected with the second region of the sixth active layer (which is also the second region of the seventh active layer) through the via.

In an exemplary implementation mode, an orthographic projection of the fifth via V5 on the base substrate is within a range of an orthographic projection of the first region of the fourth active layer on the base substrate, the sixth insulation layer, the fifth insulation layer, the fourth insulation layer, the third insulation layer, and the second insulation layer within the fifth via V5 are etched away to expose a surface of the first region of the fourth active layer, and the fifth via V5 is configured such that a third connection electrode subsequently formed is connected with the first region of the fourth active layer through the via.

In an exemplary implementation mode, an orthographic projection of the sixth via V6 on the base substrate is within a range of an orthographic projection of the second region of the third active layer (which is also the first region of the sixth active layer) on the base substrate, the sixth insulation layer, the fifth insulation layer, the fourth insulation layer, the third insulation layer, and the second insulation layer within the sixth via V6 are etched away to expose a surface of the second region of the third active layer (which is also the first region of the sixth active layer), and the sixth via V6 is configured such that a fifth connection electrode subsequently formed is connected with the second region of the third active layer (which is also the first region of the sixth active layer) through the via.

In an exemplary implementation mode, an orthographic projection of the seventh via V7 on the base substrate is within a range of an orthographic projection of the first region of the seventh active layer on the base substrate, the sixth insulation layer, the fifth insulation layer, the fourth insulation layer, the third insulation layer, and the second insulation layer within the seventh via V7 are etched away to expose a surface of the first region of the seventh active layer, and the seventh via V7 is configured such that a second initial signal line formed subsequently is connected with the first region of the seventh active layer through the via.

In an exemplary implementation mode, an orthographic projection of the eighth via V8 on the base substrate is within a range of an orthographic projection of the first region of the first active layer on the base substrate, the sixth insulation layer and the fifth insulation layer within the eighth via V8 are etched away to expose a surface of the first region of the first active layer, and the eighth via V8 is configured such that a subsequently formed second connection electrode is connected with the first region of the first active layer through the via.

In an exemplary implementation mode, an orthographic projection of the ninth via V9 on the base substrate is within a range of an orthographic projection of the second region of the second active layer on the base substrate, the sixth insulation layer and the fifth insulation layer within the ninth via V9 are etched away to expose a surface of the second region of the second active layer, and the ninth via V9 is configured such that a subsequently formed fifth connection electrode is connected with the second region of the second active layer through the via.

In an exemplary implementation mode, an orthographic projection of the tenth via V10 on the base substrate is within a range of an orthographic projection of the second region of the first active layer (which is also the first region of the second active layer) on the base substrate, the sixth insulation layer and the fifth insulation layer within the tenth via V10 are etched away to expose a surface of the second region of the first active layer (which is also the first region of the second active layer), and the tenth via V10 is configured such that a first connection electrode subsequently formed is connected with the second region of the first active layer (which is also the first region of the second active layer) through the via.

In an exemplary implementation mode, an orthographic projection of the eleventh via V11 on the base substrate is within a range of an orthographic projection of the first initial signal line 31 on the base substrate, the sixth insulation layer, the fifth insulation layer, and the fourth insulation layer within the eleventh via V11 are etched away to expose a surface of the first initial signal line 31, and the eleventh via V11 is configured such that a second connection electrode formed subsequently is connected with the first initial signal line 31 through the via.

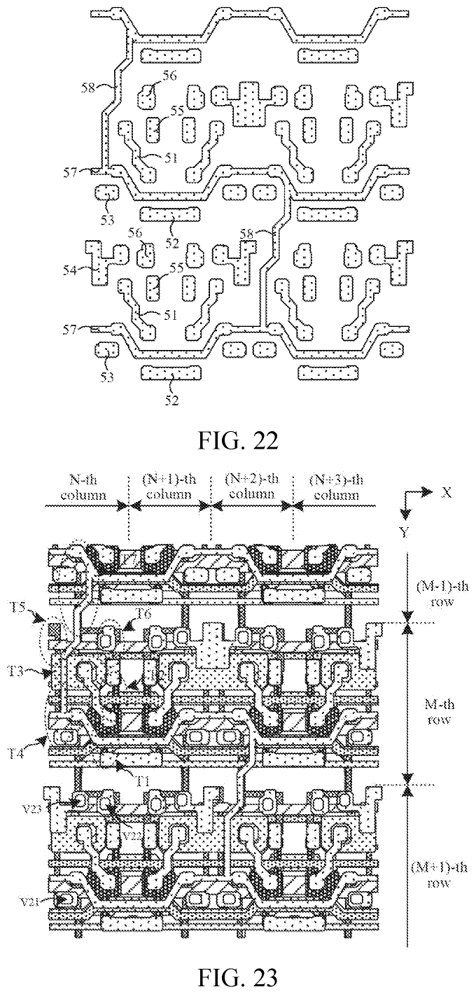

In an exemplary implementation mode, a plurality of vias of adjacent unit columns may be mirror symmetrical with respect to a center line. For example, a plurality of vias of the N-th column and a plurality of vias of the (N+1)-th column may be mirror symmetrical with respect to a center line, the plurality of vias of the (N+1)-th column and a plurality of vias of the (N+2)-th column may be mirror symmetrical with respect to a center line, and the plurality of vias of the (N+2)-th column and a plurality of vias of the (N+3)-th column may be mirror symmetrical with respect to a center line. In an exemplary implementation mode, shapes of a plurality of vias in a plurality of unit rows may be substantially the same.
(8) A pattern of a fourth conductive layer is formed. In an exemplary implementation mode, forming a fourth conductive layer may include: depositing a fourth conductive thin film on the base substrate on which the aforementioned patterns are formed, patterning the fourth conductive thin film using a patterning process to form a fourth conductive layer disposed on the sixth insulation layer, as shown in FIG. 21 and FIG. 22, FIG. 22 is a schematic plan view of the fourth conductive layer in FIG. 21. In an exemplary implementation mode, the fourth conductive layer may be referred to as a first source-drain metal (SD1) layer.

In an exemplary implementation mode, a fourth conductive layer of each circuit unit at least includes a first connection electrode 51, a second connection electrode 52, a third connection electrode 53, a fourth connection electrode 54, a fifth connection electrode 55, a sixth connection electrode 56, a second initial signal line 57, and a second initial connection line 58.

In an exemplary implementation mode, the first connection electrode 51 may be in a fold line shape of which a main body portion extends along the second direction Y, a first end of the first connection electrode 51 is connected with the first electrode plate 23 through the first via V1, and a second end of the first connection electrode 51, after extending along the second direction Y, is connected with the second region of the first active layer (which is also the first region of the second active layer) through the tenth via V10, so that the first electrode plate 23, the second electrode of the first transistor T1, and the first electrode of the second transistor T2 have a same potential. In an exemplary implementation mode, the first connection electrode 51 may simultaneously serve as the second electrode of the first transistor T1 and the first electrode of the second transistor T2 (a second node N2 of a pixel drive circuit).

In an exemplary implementation mode, the second connection electrode 52 may be in a strip shape extending along the first direction X, a first end of the second connection electrode 52 is connected with the first region of the first active layer through the eighth via V8, and a second end of the second connection electrode 52 is connected with the first initial signal line 31 through the eleventh via V11, so that a first initial voltage transmitted by the first initial signal line 31 is written into the first electrode of the first transistor T1. In an exemplary implementation mode, the second connection electrode 52 may serve as the first electrode of the first transistor T1.

In an exemplary implementation mode, in each unit row, a second connection electrode 52 of the N-th column and a second connection electrode 52 of the (N+1)-th column may be of an interconnected integral structure, and a second connection electrode 52 of the (N+2)-th column and a second connection electrode 52 of the (N+3)-th column may be of an interconnected integral structure.

In an exemplary implementation mode, the third connection electrode 53 may have a rectangular shape, and the third connection electrode 53 is connected with the first region of the fourth active layer through the fifth via V5. In an exemplary implementation mode, the third connection electrode 53 may serve as a first electrode of the fourth transistor T4, and the third connection electrode 53 is configured to be connected with an eleventh connection electrode formed subsequently.

In an exemplary implementation mode, the fourth connection electrode 54 may have a shape of a “Y”, a first end of the fourth connection electrode 54 is connected with the second electrode plate 34 through the second via V2, and a second end of the fourth connection electrode 54 is connected with the first region of the fifth active layer through the third via V3, thus it is achieved that a first electrode of the fifth transistor T5 and the second electrode plate 34 of the storage capacitor in the circuit unit have a same potential. In an exemplary implementation mode, the fourth connection electrode 54 may serve as the first electrode of the fifth transistor T5, and the fourth connection electrode 54 is configured to be connected with a shielding electrode formed subsequently.

In an exemplary implementation mode, in at least one unit row, a fourth connection electrode 54 in the (N+1)-th column and a fourth connection electrode 54 in the (N+2)-th column may be of an interconnected integral structure. In an exemplary implementation mode, since a fourth connection electrode 54 in each circuit unit is connected with the first power supply line formed subsequently, it may be ensured that fourth connection electrodes 54 of adjacent circuit units have a same potential by forming the fourth connection electrodes 54 of adjacent circuit units into an interconnected integral structure, so that first electrodes of fifth transistors T5 in adjacent circuit units have a same potential and second electrode plates 34 of storage capacitors in the adjacent circuit units have a same potential, which is beneficial to improving uniformity of a panel, avoiding poor display of the display substrate, and ensuring a display effect of the display substrate.

In an exemplary implementation mode, an orthographic projection of the fourth connection electrode 54 on the base substrate is at least partially overlapped with an orthographic projection of the second region of the seventh active layer on the base substrate, and the fourth connection electrode 54 having a constant potential may play a shielding role to ensure stability of a potential of a key node in the pixel drive circuit.

In an exemplary implementation mode, the fifth connection electrode 55 may be in a shape of a rectangle, a first end of the fifth connection electrode 55 is connected with the second region of the third active layer (which is also the first region of the sixth active layer) through the sixth via V6, and a second end of the fifth connection electrode 55 is connected with the second region of the second active layer through the ninth via V9. In an exemplary implementation mode, the fifth connection electrode 55 may simultaneously serve as a second electrode of the second transistor T2, a second electrode of the third transistor T3, and a first electrode of the sixth transistor T6 (a third node N3 of the pixel drive circuit).

In an exemplary implementation mode, the sixth connection electrode 56 may be in a polygonal shape, and the sixth connection electrode 56 is connected with the second region of the sixth active layer (which is also the second region of the seventh active layer) through the fourth via V4. In an exemplary implementation mode, the sixth connection electrode 56 may serve as a second electrode of the sixth transistor T6 and a second electrode of the seventh transistor T7 simultaneously, and the sixth connection electrode 56 is configured to be connected with a twelfth connection electrode formed subsequently.

In an exemplary implementation mode, the second initial signal line 57 may have a shape of a fold line with a main body portion extending along the first direction X, and a second initial signal line 57 in the circuit unit of the M-th row may be disposed on a side of the storage capacitor close to the circuit unit of the (M+1)-th row, and the second initial signal line 57 in the circuit unit of the M-th row is connected with a first region of a seventh active layer in the circuit unit of the (M+1)-th row through the seventh via V7, so that a second initial voltage transmitted by the second initial signal line 57 is written into a first electrode of the seventh transistor T7. Since the second initial signal line 57 is connected with first regions of all seventh active layers in a unit row, it may be ensured that the first electrodes of all the seventh transistors T7 in the unit row have a same potential, which is beneficial to improving uniformity of a panel, avoiding poor display of the display substrate, and ensuring a display effect of the display substrate.

In an exemplary implementation mode, the second initial connection line 58 may be in a shape of a fold line with a main body portion extending along the second direction Y, and the second initial connection line 58 may be disposed between two second initial signal lines 57 adjacent in the second direction Y and connected with the two second initial signal lines 57, respectively. Thus, the second initial signal line 57 extending along the first direction X and the second initial connection line 58 extending along the second direction Y constitute an initial signal line with a network communication structure in a display region, which may not only reduce a resistance of the initial signal line to a maximum extent, reduce voltage drop of an initial voltage, effectively improve uniformity of the initial voltage in the display substrate, effectively improve uniformity within a signal plane, and effectively enhance display uniformity, but also enable a potential of a fourth node (anode) of the pixel drive circuit in a reset stage to be more uniform, lighting up speeds of light emitting devices to be easier to keep consistent, thus improving display attribute and display quality.

In an exemplary implementation mode, the second initial connection line 58 may be disposed in an odd-numbered unit column or may be disposed in an even-numbered unit column, that is, one second initial connection line 58 is disposed in two unit columns.

In an exemplary implementation mode, in two adjacent unit rows, a unit column in which a second initial connection line 58 is located in one unit row is different from a unit column in which a second initial connection line 58 is located in the other unit row. For example, a second initial connection line 58 connected with a second initial signal line 57 in an (M−1)-th row and a second initial signal line 57 in the M-th row, respectively, may be located in a circuit unit of the N-th column, and a second initial connection line 58 connected with the second initial signal line 57 in the M-th row and a second initial signal line 57 in the (M+1)-th row, respectively, may be located in a circuit unit of the (N+2)-th column.

In an exemplary implementation mode, the second initial signal line 57 and the second initial connection line 58 are formed synchronously through a same patterning process and are of an interconnected integral structure.

In an exemplary implementation mode, first connection electrodes 51 to sixth connection electrodes 56 and second initial signal lines 57 of adjacent unit columns may be mirror symmetrical with respect to a center line. In an exemplary implementation mode, shapes of first connection electrodes 51 to sixth connection electrodes 56 and second initial signal lines 57 in a plurality of unit rows may be substantially the same.
(9) A pattern of a first planarization layer is formed. In an exemplary implementation mode, forming a pattern of a first planarization layer may include: coating a first planarization thin film on the base substrate on which the aforementioned patterns are formed, patterning the first planarization thin film using a patterning process to form a first planarization layer covering the pattern of the fourth conductive layer, and the first planarization layer is provided with a plurality of vias, as shown in FIG. 23.

In an exemplary implementation mode, a plurality of vias in each circuit unit at least include a twenty-first via V21, a twenty-second via V22, and a twenty-third via V23.

In an exemplary implementation mode, an orthographic projection of the twenty-first via V21 on the base substrate is located within a range of an orthographic projection of the third connection electrode 53 on the base substrate, the first planarization layer within the twenty-first via V21 is etched away to expose a surface of the third connection electrode 53, and the twenty-first via V21 is configured such that an eleventh connection electrode formed subsequently is connected with the third connection electrode 53 through the via.

In an exemplary implementation mode, an orthographic projection of the twenty-second via V22 on the base substrate is within a range of an orthographic projection of the sixth connection electrode 56 on the base substrate, the first planarization layer within the twenty-second via V22 is etched away to expose a surface of the sixth connection electrode 56, and the twenty-second via V22 is configured such that a twelfth connection electrode formed subsequently is connected with the sixth connection electrode 56 through the via.

In an exemplary implementation mode, an orthographic projection of the twenty-third via V23 on the base substrate is within a range of an orthographic projection of the fourth connection electrode 54 on the base substrate, the first planarization layer within the twenty-third via V23 is etched away to expose a surface of the fourth connection electrode 54, and the twenty-third via V232 is configured such that a shielding electrode formed subsequently is connected with the fourth connection electrode 54 through the via.

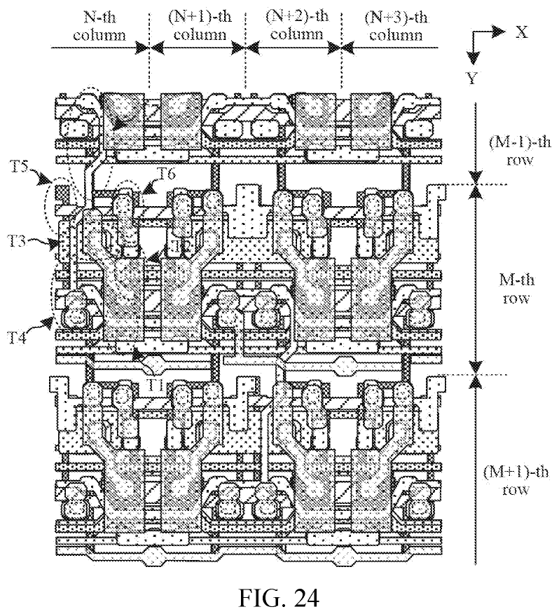

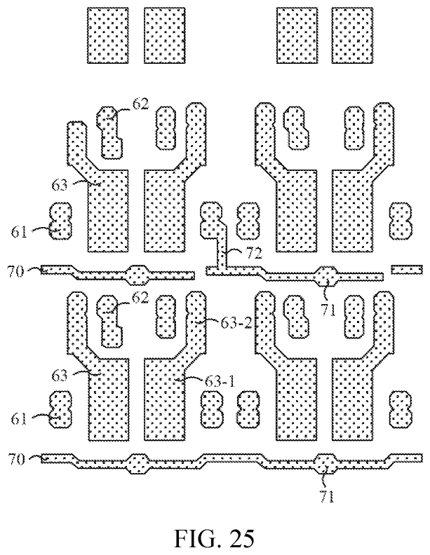

In an exemplary implementation mode, a plurality of vias on first planarization layers of adjacent unit columns may be mirror symmetrical with respect to a center line. In an exemplary implementation mode, shapes of a plurality of vias on first planarization layers in a plurality of unit rows may be substantially the same.
(10) A pattern of a fifth conductive layer is formed. In an exemplary implementation mode, forming a fifth conductive layer may include: depositing a fifth conductive thin film on the base substrate on which the above-mentioned patterns are formed, patterning the fifth conductive thin film using a patterning process to form a fifth conductive layer disposed on the first planarization layer, as shown in FIG. 24 and FIG. 25, and FIG. 25 is a schematic plan view of the fifth conductive layer in FIG. 24. In an exemplary implementation mode, the fifth conductive layer may be referred to as a second source-drain metal (SD2) layer.

In an exemplary implementation mode, a fifth conductive layer of each circuit unit at least includes an eleventh connection electrode 61, a twelfth connection electrode 62, and a shielding electrode 63.

In an exemplary implementation mode, the eleventh connection electrode 61 may be in a shape of a strip with a main body portion extending along the second direction Y, the eleventh connection electrode 61 is connected with the third connection electrode 53 through the twenty-first via V21, the eleventh connection electrode 61 is configured to be connected with a data signal line formed subsequently, and the eleventh connection electrode 61 may be referred to as a data connection electrode.

In an exemplary implementation mode, the twelfth connection electrode 62 may be in a polygonal shape, the twelfth connection electrode 62 is connected with the sixth connection electrode 56 through the twenty-second via V22, and the twelfth connection electrode 62 is configured to be connected with an anode connection electrode formed subsequently.

In an exemplary implementation mode, the shielding electrode 63 may be in a shape of a block with a main body portion extending along the second direction Y, the shielding electrode 63 is connected with the fourth connection electrode 54 through the twenty-third via V23, and the shielding electrode 63 is configured to be connected with a first power supply line formed subsequently.

In an exemplary implementation mode, the shielding electrode 63 may include a shielding main body portion 63-1 and a shielding connection portion 63-2. The shielding main body portion 63-1 may be in a shape of a rectangle, corners of the rectangle may be provided with chamfers, an orthographic projection of the shielding main body portion 63-1 on the base substrate is at least partially overlapped with an orthographic projection of the first connection electrode 51 on the base substrate, and the orthographic projection of the shielding main body portion 63-1 on the base substrate is at least partially overlapped with an orthographic projection of the second region of the first active layer and the first region of the second active layer on the base substrate. The shielding connection portion 63-2 may have a shape of a strip extending along the second direction Y. A first end of the shielding connection portion 63-2 is connected with the shielding main body portion 63-1. A second end of the shielding connection portion 63-2, after extending to a direction away from the shielding main body portion 63-1, is connected with the fourth connection electrode 54 through the twenty-third via V23. An orthographic projection of the shielding connection portion 63-2 on the base substrate is at least partially overlapped with an orthographic projection of the first connection electrode 51 on the base substrate.

In an exemplary implementation mode, since the shielding electrode 63 completely shields the second region of the first active layer and the first region of the second active layer, the shielding electrode 63 may block light emitted by a light emitting device and light reflected by a film layer from irradiating an oxide transistor, may prevent the oxide transistor from characteristic drift due to illumination, thus improving electrical characteristics of the oxide transistor. Since the shielding electrode 63 is connected with the first power supply line formed subsequently, the shielding electrode 63 with a constant potential may not only effectively shield an influence of data voltage jump and another signals on the second node N2 in the pixel drive circuit, avoid an influence of the data voltage jump and another signal on a potential of the second node N2, effectively avoid deterioration of cross talk, but also avoid a display difference caused by a case that second connection lines are disposed in part of circuit units and no second connection line is disposed in part of circuit units, thus improving a display effect.

In an exemplary implementation mode, the fourth conductive layer may further include a first connection line 70, a first lap block 71, and a data connection block 72.

In an exemplary implementation mode, the first connection line 70 may have a shape of a fold line with a main body portion extending along the first direction X, a first connection line 70 of the circuit unit of the M-th row may be disposed on a side of the shielding electrode 63 close to the circuit unit of the (M+1)-th row, and the first connection line 70 is configured as a lateral trace in a data connection line.

In an exemplary implementation mode, in at least one unit row, a fracture may be disposed on a first connection line 70, the first connection line 70 on one side of the fracture serves as a lateral trace in a data connection line, and the first connection line 70 on the other side of the fracture serves as a dummy trace, so as to ensure etching uniformity of the display substrate.

In an exemplary implementation mode, the first lap block 71 may be in a polygonal shape, located between adjacent unit columns, and connected with the first connection line 70. For example, a first lap block 71 may be disposed between the N-th column and the (N+1)-th column and a first lap block 71 may be disposed between the (N+2)-th column and the (N+3)-th column. In an exemplary implementation mode, a portion of first lap blocks 71 are configured to be connected with a second connection line formed subsequently, and another portion of the first lap blocks 71 serve as a dummy lap structure to ensure etching uniformity of the display substrate.

In an exemplary implementation mode, the data connection block 72 may have a shape of a strip extending along the second direction Y, a first end of the data connection block 72 is connected with the first connection line 70, and a second end of the data connection block 72 is connected with the third connection electrode 53.

In an exemplary implementation mode, in at least one circuit unit, the first connection line 70, the first lap block 71, and the data connection block 72 may be formed synchronously through a same patterning process and are of an interconnected integral structure.

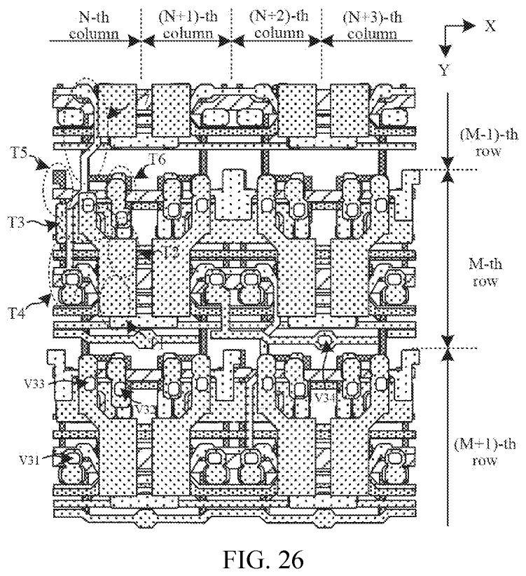

In an exemplary implementation mode, eleventh connection electrodes 61, twelfth connection electrodes 62, and shielding electrodes 63 of adjacent unit columns may be mirror symmetrical with respect to a center line. In an exemplary implementation mode, shapes of eleventh connection electrodes 61, twelfth connection electrodes 62, and shielding electrodes 63 in a plurality of unit rows may be substantially the same.
(11) A pattern of a second planarization layer is formed. In an exemplary implementation mode, forming a pattern of a second planarization layer may include: coating a second planarization thin film on the base substrate on which the aforementioned patterns are formed, patterning the second planarization thin film using a patterning process to form a second planarization layer covering the pattern of the fifth conductive layer, wherein a plurality of vias are disposed on the second planarization layer, as shown in FIG. 26.

In an exemplary implementation mode, a plurality of vias in each circuit unit at least includes a thirty-first via V31, a thirty-second via V32, and a thirty-third via V33.

In an exemplary implementation mode, an orthographic projection of the thirty-first via V31 on the base substrate is within a range of an orthographic projection of the eleventh connection electrode 61 on the base substrate, the second planarization layer within the thirty-first via V31 is etched away to expose a surface of the eleventh connection electrode 61, and the thirty-first via V31 is configured such that a data signal line formed subsequently is connected with the eleventh connection electrode 61 through the via. In an exemplary implementation mode, the thirty-first via V31, on the eleventh connection electrode 61 (data connection electrode), connected with the first connection line 70 may be referred to as a first lap via.

In an exemplary implementation mode, an orthographic projection of the thirty-second via V32 on the base substrate is within a range of an orthographic projection of the twelfth connection electrode 62 on the base substrate, the second planarization layer within the thirty-second via V32 is etched away to expose a surface of the twelfth connection electrode 62, and the thirty-second via V32 is configured such that an anode connection electrode formed subsequently is connected with the twelfth connection electrode 62 through the via.

In an exemplary implementation mode, an orthographic projection of the thirty-third via V33 on the base substrate is within a range of an orthographic projection of the shielding connection portion 63-2 in the shielding electrode 63 on the base substrate, the second planarization layer within the thirty-third via V33 is etched away to expose a surface of the shielding connection portion 63-2, and the thirty-third via V33 is configured such that a first power supply line formed subsequently is connected with the shielding electrode 63 through the via.

In an exemplary implementation mode, the plurality of vias on the second planarization layer may further include a thirty-fourth via V34. An orthographic projection of the thirty-fourth via V34 on the base substrate is within a range of an orthographic projection of the first lap block 71 on the base substrate, the second planarization layer within the thirty-fourth via V34 is etched away to expose ae surface of the first lap block 71, and the thirty-fourth via V34 is configured such that a second connection line formed subsequently is connected with the first connection line 70 through the via. In an exemplary implementation mode, part of the first lap block 71 is provided with the thirty-fourth via V34, and the thirty-fourth via V34 may be referred to as a second lap via.

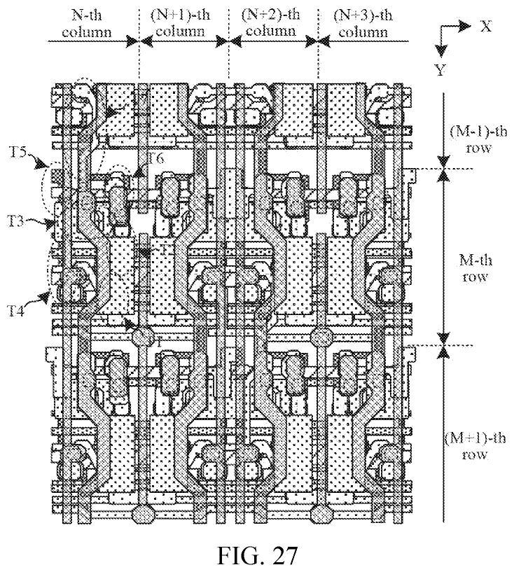

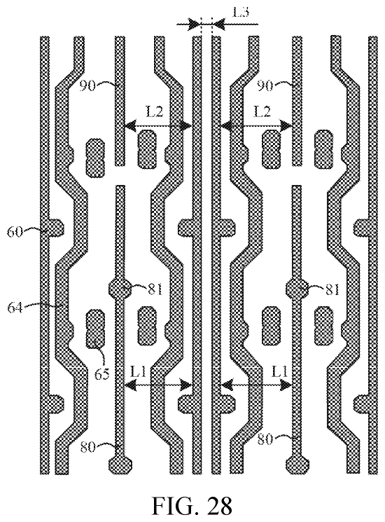

In an exemplary implementation mode, thirty-first vias V31, thirty-second vias V32, and thirty-third vias V33 of adjacent unit columns may be mirror symmetrical with respect to a center line. In an exemplary implementation mode, shapes of thirty-first vias V31, thirty-second vias V32, and thirty-third vias V33 in a plurality of unit rows may be substantially the same.
(12) A pattern of a sixth conductive layer is formed. In an exemplary implementation mode, forming a sixth conductive layer may include: depositing a sixth conductive thin film on the base substrate on which the aforementioned patterns are formed, patterning the sixth conductive thin film using a patterning process to form a sixth conductive layer disposed on the second planarization layer, as shown in FIG. 27 and FIG. 28, and FIG. 28 is a schematic plan view of the sixth conductive layer in FIG. 27. In an exemplary implementation mode, the sixth conductive layer may be referred to as a third source-drain metal (SD3) layer.

In an exemplary implementation mode, a sixth conductive layer of each circuit unit at least includes a data signal line 60, a first power supply line 64, and an anode connection electrode 65.

In an exemplary implementation mode, the data signal line 60 may have a shape of a line with a main body portion extending along the second direction Y, and the data signal line 60 is connected with the eleventh connection electrode 61 through the thirty-first via V31. Since the eleventh connection electrode 61 is connected with the third connection electrode 53 through a via and the third connection electrode 53 is connected with the first region of the fourth active layer through a via, a connection between the data signal line 60 and the first electrode of the fourth transistor T4 is achieved, and the data signal line 60 may write a data signal into the first electrode of the fourth transistor T4.

In an exemplary implementation mode, since the data signal line is disposed in the third source-drain metal (SD3) layer and the first planarization layer and the second planarization layer which are relatively thick are spaced between the data signal line and a corresponding signal line, a distance between the data signal line and the corresponding signal line is increased, and a parasitic capacitance between the data signal line and the corresponding signal line is reduced, thereby effectively reducing a capacitive load of the data signal line.

In an exemplary implementation mode, the first power supply line 64 may be in a shape of a fold line with a main body portion extending along the second direction Y, and the first power supply line 64 is connected with the shielding connection portion 63-2 of the shielding electrode 63 through the thirty-third via V33. Since the shielding electrode 63 is connected with the fourth connection electrode 54 through a via and the fourth connection electrode 54 is connected with the first region of the fifth active layer and the second electrode plate 34 through a via, a connection between the first power supply line 64 and the first electrode of the fifth transistor T5 and the second electrode plate 34 is achieved, the first power supply line 64 may write a power supply signal into the first electrode of the fifth transistor T5, and the first electrode of the fifth transistor T5 and the second electrode plate 34 of the storage capacitor have a same potential.

In an exemplary implementation mode, the first power supply line 64 may be a fold line with unequal widths, which not only may facilitate a layout of a pixel structure, but also may reduce a parasitic capacitance between the first power supply line and the data signal line.

In an exemplary implementation mode, the anode connection electrode 65 may be in a polygonal shape, the anode connection electrode 65 is connected with the twelfth connection electrode 62 through the thirty-second via V32, and the anode connection electrode 65 is configured to be connected with an anode formed subsequently. Since the twelfth connection electrode 62 is connected with the sixth connection electrode 56 through a via, and the sixth connection electrode 56 is connected with the second region of the sixth active layer and the second region of the seventh active layer through a via, a connection between the anode formed subsequently, and the second electrode of the sixth transistor T6 and the second electrode of the seventh transistor T7 may be achieved, and the pixel drive circuit may drive a light emitting device to emit light.

In an exemplary implementation mode, the sixth conductive layer may further include a second connection line 80, a second lap block 81, and a power supply trace 90.

In an exemplary implementation mode, the second connection line 80 may have a shape of a line with a main body portion extending along the second direction Y, may be located at a gap between pixel drive circuits of adjacent unit columns, and the second connection line 80 is connected with the first lap block 71 through the thirty-fourth via V34. Since the first lap block 71 is connected with the first connection line 70, a connection between the second connection line 80 and the first connection line 70 is achieved. Since the first connection line 70 is connected with the eleventh connection electrode 61 through the data connection block 72 and the eleventh connection electrode 61 is connected with the data signal line 60 through a via, a sequential connection between the data signal line 60, the first connection line 70, and the second connection line 80 is achieved.

In an exemplary implementation mode, the second lap block 81 may be in a polygonal shape, located between adjacent unit columns, and connected with the second connection line 80. For example, the second lap block 81 may be disposed between the N-th column and the (N+1)-th column, and the second lap block 81 may be disposed between the (N+2)-th column and the (N+3)-th column. In an exemplary implementation mode, an orthographic projection of the second lap block 81 on the base substrate is at least partially overlapped with an orthographic projection of the first lap block 71 on the base substrate, part of the second lap block 81 is connected with the first lap block 71 through the thirty-fourth via V34, and the other part of the second lap block 81 serves as a dummy lap structure to ensure etching uniformity of the display substrate.

In an exemplary implementation mode, since a mirror symmetry structure is adopted for pixel drive circuits of the display region, pixel drive circuits of adjacent unit columns are mirror symmetrical, a gap may be formed between the pixel drive circuits of adjacent unit columns through center compression without changing a size of a circuit unit, so that a second connection line extending longitudinally in the display region may be disposed at a gap between adjacent pixel drive circuits, a distance between the second connection line and the data signal line is maximized, and an interference caused by capacitive coupling between the second connection line and the data signal line is minimized.

In an exemplary implementation mode, at least one second connection line 80 may be disposed between two data signal lines 60 of adjacent unit columns, the two data signal lines 60 may be mirror symmetrical with respect to a center line, and the two data signal lines 60 may be mirror symmetrical with respect to the second connection line 80.

In an exemplary implementation mode, a minimum distance L1 between at least one second connection line 80 and an adjacent data signal line 60 in the first direction X may be greater than a minimum distance L3 between two data signal lines 60 in adjacent unit columns in the first direction X.

In an exemplary implementation mode, since the second connection line is disposed in the third source-drain metal (SD3) layer, and the first planarization layer and the second planarization layer which are relatively thick are spaced between the second connection line and a corresponding signal line, a distance between the second connection line and the corresponding signal line is increased, and a parasitic capacitance between the second connection line and the corresponding signal line is reduced, thereby effectively reducing a capacitance load of the second connection line.

In an exemplary implementation mode, since the first connection line is disposed in the second source-drain metal (SD2) layer and the second connection line is disposed in the third source-drain metal (SD3) layer, the first connection line and the second connection line may be connected with only one planarization layer via, thereby minimizing occupied space and facilitating achievement of high-resolution display.

In an exemplary implementation mode, the power supply trace 90 may have a shape of a line with a main body portion extending along the second direction Y, and is located between part of adjacent unit columns. Between at least one unit column, only the power supply trace 90 may be disposed without the second connection line 80. Between at least one unit column, the second connection line 80 and the power supply line 90 may be respectively disposed, the power supply line 90 and the second connection line 80 may be located on a same straight line extending along the second direction Y, and a fracture is disposed between the power supply line 90 and the second connection line 80, and the fracture is configured to achieve insulation between the power supply line 90 and the second connection line 80.

In an exemplary implementation mode, at least one power supply trace 90 may be disposed between two data signal lines 60 of adjacent unit columns, and the two data signal lines 60 may be mirror symmetrical with respect to the power supply trace 90.

In an exemplary implementation mode, a minimum distance L2 between at least one power supply trace 90 and an adjacent data signal line 60 in the first direction X may be greater than a minimum distance L3 between two data signal lines 60 in adjacent unit columns in the first direction X.

In an exemplary implementation mode, a plurality of power supply traces 90 may be traces that continuously provide low-voltage signals. For example, a power supply trace may be a second power supply line VSS. The plurality of power supply traces 90 may be connected with power supply lead lines disposed in a bonding region or a bezel region. In the present disclosure, a structure in which a low-voltage power supply line is disposed in a sub-pixel (VSS in pixel) is achieved by disposing a power supply trace in the display region, which not only may effectively reduce a resistance of a power supply signal line, effectively reduce voltage drop of a low-voltage power supply signal, and achieve low power consumption, but also may effectively improve uniformity of power supply signals in the display substrate, effectively improve display uniformity, and improve display attribute and display quality. In addition, the structure in which the low-voltage power supply line is disposed in the sub-pixel may greatly reduce a width of a power supply lead line in the bezel region and the bonding region, which is beneficial to achievement of a narrow bezel.

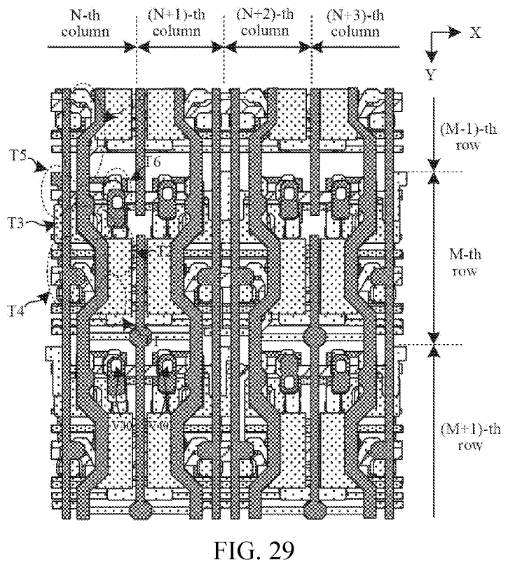

In an exemplary implementation mode, data signal lines 60, first power supply lines 64, and anode connection electrodes 65 of adjacent unit columns may be mirror symmetrical with respect to a center line. In an exemplary implementation mode, shapes of data signal lines 60, first power supply lines 64, and anode connection electrodes 65 in a plurality of unit rows may be substantially the same.
(13) A pattern of a third planarization layer is formed. In an exemplary implementation mode, forming a pattern of a third planarization layer may include: coating a third planarization thin film on the base substrate on which the above-mentioned patterns are formed, patterning the third planarization thin film using a patterning process to form a third planarization layer covering the pattern of the sixth conductive layer, wherein the third planarization layer is provided with a plurality of vias, as shown in FIG. 29.

In an exemplary implementation mode, a via of each circuit unit at least includes an anode via V40. An orthographic projection of the anode via V40 on the base substrate is within a range of an orthographic projection of the anode connection electrode 65 on the base substrate, the third planarization layer within the anode via V40 is removed to expose a surface of the anode connection electrode 65, and the anode via V40 is configured such that an anode formed subsequently is connected with the anode connection electrode 65 through the via.

So far, preparation of a drive structure layer on the base substrate is completed. In a plane parallel to the display substrate, the drive structure layer may include a plurality of circuit units, each of which may include a pixel drive circuit, and a first scan signal line, a second scan signal line, a third scan signal line, a light emitting signal line, a data signal line, a first power supply line, a first initial signal line, and a second initial signal line connected with the pixel drive circuit. In a plane perpendicular to the display substrate, the drive structure layer may include a shielding layer, a first insulation layer, a first semiconductor layer, a second insulation layer, a first conductive layer, a third insulation layer, a second conductive layer, a fourth insulation layer, a second semiconductor layer, a fifth insulation layer, a third conductive layer, a sixth insulation layer, a fourth conductive layer, a first planarization layer, a fifth conductive layer, a second planarization layer, a sixth conductive layer, and a third planarization layer disposed sequentially on the base substrate. The shielding layer may at least include a shielding electrode, the first semiconductor layer may at least include active layers of a third transistor to a seventh transistor, the first conductive layer may at least include a first scan signal line, a light emitting signal line, and a first electrode plate of a storage capacitor, the second conductive layer may at least include a first initial signal line and a second electrode plate of the storage capacitor, the second semiconductor layer may at least include active layers of a first transistor to a second transistor, the third conductive layer may at least include a second scan signal line and a third scan signal line, the fourth conductive layer may at least include a second initial signal line, a second initial connection line, and a plurality of connection electrodes, the fifth conductive layer may at least include a shielding electrode and a first connection line, and the sixth conductive layer may at least include a data signal line, a first power supply line, a second power supply line, and a second connection line.

In an exemplary implementation mode, the base substrate may be a flexible base substrate or may be a rigid base substrate. The rigid base substrate may include, but is not limited to, one or more of glass and quartz, and the flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In an exemplary implementation mode, the flexible base substrate may include a first flexible material layer, a first inorganic material layer, a semiconductor layer, a second flexible material layer, and a second inorganic material layer which are stacked. Materials of the first flexible material layer and the second flexible material layer may be Polyimide (P1), Polyethylene Terephthalate (PET), or a polymer soft film subjected to a surface treatment, etc. Materials of the first inorganic material layer and the second inorganic material layer may be Silicon Nitride (SiNx), Silicon Oxide (SiOx), or the like, so as to improve a water-oxygen resistance capability of the base substrate. The first inorganic material layer and the second inorganic material layer are also referred to as barrier layers. A material of the semiconductor layer may be amorphous silicon (a-si).

In an exemplary implementation mode, the first conductive layer, the second conductive layer, the third conductive layer, the fourth conductive layer, the fifth conductive layer, and the sixth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The first insulation layer, the second insulation layer, the third insulation layer, the fourth insulation layer, the fifth insulation layer, and the sixth insulation layer may be made of any one or more of Silicon Oxide (SiOx), Silicon Nitride (SiNx), and Silicon OxyNitride (SiON), and may be a single layer, a multi-layer, or a composite layer. The first insulation layer may be referred to as a buffer layer, the second insulation layer, the third insulation layer, the fourth insulation layer, and the fifth insulation layer may be referred to as Gate Insulation (GI) layers, and the sixth insulation layer may be referred to as an Interlayer Dielectric (ILD) layer. The first planarization layer, the second planarization layer, and the third planarization layer may be made of an organic material, such as a resin.

In an exemplary implementation mode, pixel drive circuits in two adjacent circuit units in a unit row may be substantially mirror symmetrical with respect to a center line, and the center line is a straight line located between the two adjacent circuit units and extending along the second direction Y. For example, a pixel drive circuit of the N-th column and a pixel drive circuit of the (N+1)-th column may be mirror symmetrical with respect to a center line. For another example, the pixel drive circuit of the (N+1)-th column and a pixel drive circuit of the (N+2)-th column may be mirror symmetrical with respect to a center line.

In an exemplary implementation mode, that pixel drive circuits in two adjacent circuit units may be substantially mirror symmetrical with respect to the center line, which may include any one or more of following: first semiconductor layers in two adjacent circuit units in a unit row may be mirror symmetrical with respect to the center line, first conductive layers in two adjacent circuit units in a unit row may be mirror symmetrical with respect to the center line, second conductive layers in two adjacent circuit units in a unit row may be mirror symmetrical with respect to the center line, second semiconductor layers in two adjacent circuit units in a unit row may be mirror symmetrical with respect to the center line, and third conductive layers in two adjacent circuit units in a unit row may be mirror symmetrical with respect to the center line.

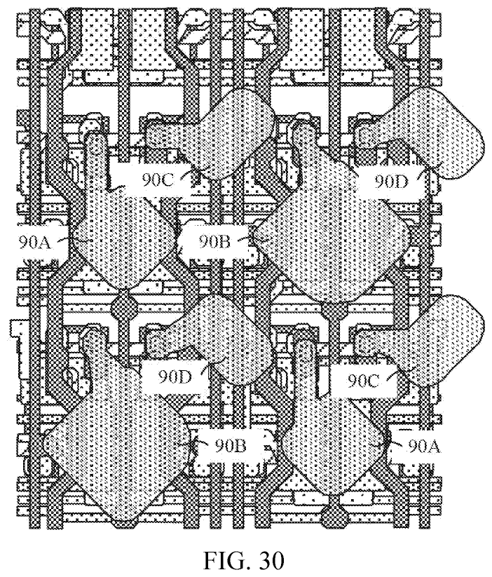

In an exemplary implementation mode, after preparation of the drive structure layer is completed, a light emitting structure layer is prepared on the drive structure layer, and a preparation process of the light emitting structure layer may include following operations.
(14) A pattern of an anode conductive layer is formed. In an exemplary implementation mode, forming a pattern of an anode conductive layer may include: depositing an anode conductive thin film on the base substrate on which the above-mentioned patterns are formed, patterning the anode conductive thin film using a patterning process to form an anode conductive layer disposed on the third planarization layer, wherein the anode conductive layer at least includes a plurality of patterns of anodes, as shown in FIG. 30.

In an exemplary implementation mode, the anode conductive layer may be of a single-layer structure, such as Indium Tin Oxide (ITO) or Indium Zinc Oxide (IZO), or may be of a multi-layer composite structure, such as ITO/Ag/ITO.

In an exemplary implementation mode, the plurality of patterns of anodes may include a first anode 90A located in a red light emitting unit emitting red light, a second anode 90B located in a blue light emitting unit emitting blue light, a third anode 90C located in a first green light emitting unit emitting green light, and a fourth anode 90D located in a second green light emitting unit emitting green light.

In an exemplary implementation mode, the first anode 90A, the second anode 90B, the third anode 90C, and the fourth anode 90D may be respectively connected with the anode connection electrode 65 of a circuit unit where they are located through the anode via V40.

In an exemplary implementation mode, at least one of the first anode 90A, the second anode 90B, the third anode 90C, and the fourth anode 90D may include an anode body portion and an anode connection portion connected with each other, the anode body portion may have a shape of a rectangle, corners of the rectangle may be provided with arc-shaped chamfers, the anode connection portion may have a strip shape, a first end of the anode connection portion is connected with the anode body portion, and a second end of the anode connection portion, after extending to a direction away from the anode body portion, is connected with the anode connection electrode 65 through the anode via V40.

In an exemplary implementation mode, an orthographic projection of the first anode, the second anode, the third anode, and the fourth anode on the base substrate is at least partially overlapped with an orthographic projection of the first power supply line on the base substrate, and an orthographic projection of the first anode and the second anode on the base substrate is at least partially overlapped with an orthographic projection of the shielding electrode on the base substrate.

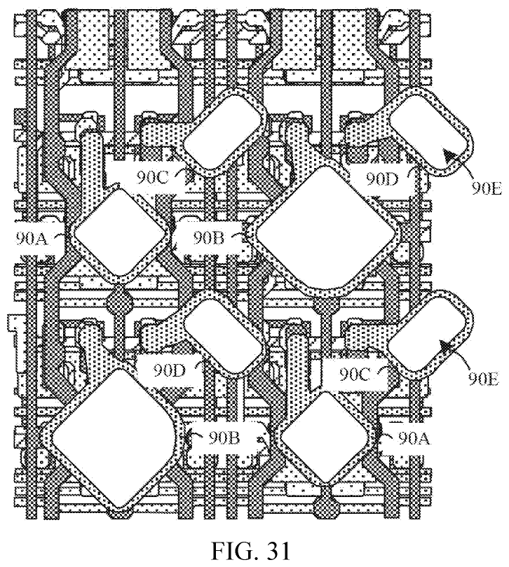

In an exemplary implementation mode, in at least one light emitting unit, an orthographic projection of the first anode on the base substrate and an orthographic projection of the first power supply line on the base substrate have a first overlapping region, and the orthographic projection of the first anode on the base substrate and an orthographic projection of the shielding electrode on the base substrate have a second overlapping region, an area of the first overlapping region is less than an area of the second overlapping region. In at least one light emitting unit, an orthographic projection of the second anode on the base substrate and an orthographic projection of the first power supply line on the base substrate have a first overlapping region, the orthographic projection of the second anode on the base substrate and an orthographic projection of the shielding electrode on the base substrate have a second overlapping region, an area of the first overlapping region is less than an area of the second overlapping region. In the present disclosure, by disposing the shielding electrode in the second source-drain metal layer SD2 and the first power supply line in the third source-drain metal layer SD3, overlapping areas of the first anode and the second anode with the first power supply line are effectively reduced, a parasitic capacitance of a fourth node N4 of the pixel drive circuit is effectively reduced, and a lighting speed of a light emitting device is improved.
(15) A pattern of a pixel definition layer is formed. In an exemplary implementation mode, forming a pattern of a pixel definition layer may include: coating a pixel definition thin film on the base substrate on which the above-mentioned patterns are formed, patterning the pixel definition thin film using a patterning process to form a pixel definition layer covering the pattern of the anode conductive layer, wherein a plurality of pixel openings 90E are disposed on the pixel definition layer, and the pixel definition thin film within the pixel openings 90E is removed to expose surfaces of the first anode 90A, the second anode 90B, the third anode 90C, and the fourth anode 90D, respectively, as shown in FIG. 31.

In an exemplary implementation mode, a subsequent preparation process may include: forming an organic emitting layer using an evaporation process or an inkjet printing process at first, subsequently forming a cathode on the organic emitting layer, and then forming an encapsulation structure layer, wherein the encapsulation structure layer may include a first encapsulation layer, a second encapsulation layer, and a third encapsulation layer which are stacked, the first encapsulation layer and the third encapsulation layer may be made of an inorganic material, the second encapsulation layer may be made of an organic material, and the second encapsulation layer is disposed between the first encapsulation layer and the third encapsulation layer, which may ensure that external water vapor cannot enter the light emitting structure layer.

As may be seen from a structure and the preparation process of the display substrate described above, in the display substrate provided by the exemplary embodiment of the present disclosure, a data connection line is disposed in a display region, so that a lead-out line of a bonding region is connected with a data signal line through the data connection line, and no fan-shaped oblique line needs to be disposed in a lead region, which effectively reduces a length of the lead region, greatly reduces a width of a lower bezel, and increases a screen-to-body ratio, which is beneficial to achieving full-screen display. In the present disclosure, by disposing the first connection line in the second source-drain metal layer and the second connection line in the third source-drain metal layer, the first connection line and the second connection line may be connected with only one planarization layer via, thereby minimizing occupied space, facilitating achievement of high-resolution display, and a resolution (PPI) of an LTPO display substrate may be increased to 480 while achieving a narrow bezel. In the present disclosure, by disposing the data signal line and the second connection line in the third source-drain metal layer, a distance between the data signal line and the second connection line, and the corresponding signal line is increased, and a parasitic capacitance between the data signal line and the second connection line, and the corresponding signal line is reduced, thereby effectively reducing a capacitance load of the data signal line and the second connection line. In the present disclosure, by adopting mirror symmetry and center compression of a pixel drive circuit and disposing the second connection line at a gap of adjacent unit columns, a distance between the second connection line and the data signal line is maximized and an interference caused by capacitive coupling between the second connection line and the data signal line is minimized. In the present disclosure, by disposing the shielding electrode in the second source-drain metal layer, on one hand, the shielding electrode may block light emitted by a light emitting device and light reflected by a film layer from irradiating an oxide transistor, may prevent characteristic drift of the oxide transistor due to illumination, and improve electrical characteristics of the oxide transistor, on the other hand, the shielding electrode may effectively shield an influence of data voltage jump and another signal on the second node N2 in the pixel drive circuit, avoid an influence of the data voltage jump and another signal on a potential of the second node N2, effectively avoid deterioration of cross talk, and may avoid a display difference caused by a case that second connection lines are disposed in part of circuit units and no second connection line is disposed in part of circuit units, thus improving a display effect. In the present disclosure, by forming the second initial signal line with the network communication structure in the display region, not only a resistance of an initial signal line is minimized, voltage drop of an initial voltage is reduced, uniformity of the initial voltage in the display substrate is effectively improved, uniformity within a signal plane is effectively improved, and display uniformity is effectively enhanced, but also a potential of the fourth node (anode) of the pixel drive circuit is enabled to be more uniform in a reset stage, a lighting up speed of a light emitting device is easier to keep consistent, thus improving display attribute and display quality. In the present disclosure, by disposing the shielding electrode in the second source-drain metal layer and the first power supply line in the third source-drain metal layer, an overlapping area of the anode with the first power supply line is effectively reduced, a parasitic capacitance of the fourth node N4 of the pixel drive circuit is effectively reduced, and a lighting up speed of a light emitting device is improved. In the present disclosure, a structure of VSS in pixel is achieved by disposing power supply traces in the display region, which may greatly reduce a width of a bezel power supply line, greatly reduce widths of left and right bezels, and increase a screen-to-body ratio, which is beneficial to achieving full-screen display. The preparation process of the present disclosure may be compatible well with an existing preparation process, and is simple in process implementation, easy to implement, high in a production efficiency, low in a production cost, and high in a yield.

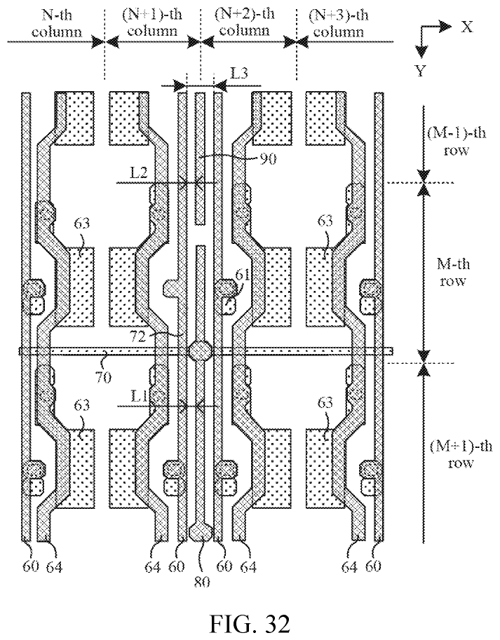

FIG. 32 is a schematic diagram of a planar structure of another display substrate according to an embodiment of the present disclosure. As shown in FIG. 12, a main body structure of the display substrate of the present exemplary embodiment is substantially similar to that of the display substrate of the above-mentioned embodiments, except that a minimum distance L1 between at least one second connection line 80 and an adjacent data signal line 60 in a first direction X may be about ½ of a minimum distance L3 between two data signal lines 60 in adjacent unit columns in the first direction X, and a minimum distance L2 between at least one power supply trace 90 and an adjacent data signal line 60 in the first direction X may be about ½ of a minimum distance L3 between two data signal lines 60 in adjacent unit columns in the first direction X.

In an exemplary implementation mode, in the display substrate shown in FIG. 8, the second connection line 80 is disposed between two data signal lines 60 spaced farther in adjacent unit columns, and in the display substrate shown in FIG. 32, a second connection line 80 is disposed between two data signal lines 60 spaced closer in adjacent unit columns.

The structure shown in the foregoing of the present disclosure and preparation process thereof are only an exemplary explanation. In an exemplary implementation mode, corresponding structures may be changed and patterning processes may be added or reduced according to actual needs, which is not limited here in the present disclosure.

In an exemplary implementation mode, the display substrate of the present disclosure may be applied to another display apparatus having a pixel drive circuit, such as quantum dot display, which is not limited here in the present disclosure.

The present disclosure also provides a preparation method of a display substrate to manufacture the display substrate provided by the embodiments described above. In an exemplary implementation mode, the display substrate includes a display region, and the preparation method includes following operations: forming a drive structure layer on a base substrate of the display region, wherein the drive structure layer at least includes a plurality of circuit units constituting a plurality of unit rows and a plurality of unit columns, a plurality of data signal lines extending along a second direction, a plurality of first connection lines extending along a first direction, and a plurality of second connection lines extending along a second direction, the first direction intersects with the second direction; a circuit unit includes a pixel drive circuit, at least one data signal line is connected with a plurality of pixel drive circuits of a unit column, first ends of the plurality of first connection lines are correspondingly connected with a plurality of data signal lines, and second ends of the plurality of first connection lines are correspondingly connected with a plurality of second connection lines; pixel drive circuits in adjacent unit columns are mirror symmetrical with respect to a center line, the center line is a straight line located between adjacent unit columns and extending along the second direction, and a second connection line is disposed at a gap between pixel drive circuits of adjacent unit columns.

Although the implementation modes disclosed in the present disclosure are described as above, the described contents are only implementation modes which are used for facilitating understanding of the present disclosure, but are not intended to limit the present disclosure. Any skilled person in the art to which the present disclosure pertains may make any modification and variation in forms and details of implementations without departing from the spirit and scope of the present disclosure. However, the patent protection scope of the present disclosure should be subject to the scope defined in the appended claims.

1. A display substrate, comprising a display region, wherein the display region comprises a drive structure layer disposed on a base substrate, the drive structure layer at least comprises a plurality of circuit units constituting a plurality of unit rows and a plurality of unit columns, a plurality of data signal lines extending along a second direction, a plurality of first connection lines extending along a first direction, and a plurality of second connection lines extending along the second direction, the first direction intersects with the second direction; a circuit unit comprises a pixel drive circuit, at least one data signal line is connected with a plurality of pixel drive circuits of a unit column, first ends of the plurality of first connection lines are correspondingly connected with the plurality of data signal lines, and second ends of the plurality of first connection lines are correspondingly connected with the plurality of second connection lines; pixel drive circuits in adjacent unit columns are mirror symmetrical with respect to a center line, the center line is a straight line located between adjacent unit columns and extending along the second direction, and a second connection line is disposed at a gap between pixel drive circuits of adjacent unit columns.

2. The display substrate according to claim 1, wherein two data signal lines in at least one adjacent unit column are mirror symmetrical with respect to the second connection line, and a minimum distance between the second connection line and an adjacent data signal line in the first direction is greater than a minimum distance between the two data signal lines in the adjacent unit columns in the first direction;
or,
two data signal lines in at least one adjacent unit column are mirror symmetrical with respect to the second connection line, and a minimum distance between the second connection line and an adjacent data signal line in the first direction is ½ of a minimum distance between the two data signal lines in the adjacent unit columns in the first direction.

3. (canceled)

4. The display substrate according to claim 1, wherein the drive structure layer further comprises a plurality of power supply traces extending along the second direction, and a power supply trace is disposed at a gap between pixel drive circuits of adjacent unit columns.

5. The display substrate according to claim 4, wherein two data signal lines in at least one adjacent unit column are mirror symmetrical with respect to the power supply trace, and a minimum distance between the power supply trace and an adjacent data signal line in the first direction is greater than a minimum distance between the two data signal lines in the adjacent unit columns in the first direction;
or,
two data signal lines in at least one adjacent unit column are mirror symmetrical with respect to the power supply trace, and a minimum distance between the power supply trace and an adjacent data signal line in the first direction is ½ of a minimum distance between the two data signal lines in the adjacent unit columns in the first direction.

6. (canceled)

7. The display substrate according to claim 1, wherein on a plane perpendicular to the display substrate, the drive structure layer comprises a plurality of conductive layers sequentially disposed on the base substrate, a first connection line and a second connection line are disposed in different conductive layers, and a data signal line and the second connection line are disposed in a same conductive layer.

8. The display substrate according to claim 7, wherein the plurality of conductive layers at least comprise a first source-drain metal layer, a second source-drain metal layer, and a third source-drain metal layer that are sequentially disposed along a direction away from the base substrate, the first connection line is disposed in the second source-drain metal layer, the data signal line and the second connection line are disposed in the third source-drain metal layer, the data signal line is connected with a first end of the first connection line through a via and the second connection line is connected with a second end of the first connection line through a via.

9. The display substrate according to claim 8, wherein the pixel drive circuit at least comprises a first transistor, a second transistor, and a storage capacitor, the first transistor at least comprises a first active layer, the second transistor at least comprises a second active layer, a second region of the first active layer and a first region of the second active layer are of an interconnected integral structure, and are connected with a first electrode plate of the storage capacitor through a first connection electrode; the second source-drain metal layer further comprises a shielding electrode, an orthographic projection of the shielding electrode on the base substrate is at least partially overlapped with an orthographic projection of the second region of the first active layer and the first region of the second active layer on the base substrate, and the orthographic projection of the shielding electrode on the base substrate is at least partially overlapped with an orthographic projection of the first connection electrode on the base substrate.

10. The display substrate according to claim 9, wherein the third source-drain metal layer further comprises a first power supply line, and the first power supply line is connected with the shielding electrode through a via.

11. The display substrate according to claim 10, wherein on a plane perpendicular to the display substrate, the display substrate further comprises a light emitting structure layer disposed on a side of the drive structure layer away from the base substrate, the light emitting structure layer comprises a plurality of light emitting units, a light emitting unit at least comprises an anode; in at least one light emitting unit, an orthographic projection of the anode on the base substrate is at least partially overlapped with an orthographic projection of the first power supply line on the base substrate, and the orthographic projection of the anode on the base substrate is at least partially overlapped with the orthographic projection of the shielding electrode on the base substrate.

12. The display substrate according to claim 11, wherein in at least one light emitting unit, an orthographic projection of the anode on the base substrate and the orthographic projection of the first power supply line on the base substrate have a first overlapping region, and the orthographic projection of the anode on the base substrate and the orthographic projection of the shielding electrode on the base substrate have a second overlapping region, an area of the first overlapping region is less than an area of the second overlapping region.

13. The display substrate according to claim 1, wherein the pixel drive circuit at least comprises a fourth transistor, a first electrode of the fourth transistor is connected with the data signal line through a data connection electrode, and in at least one circuit unit, the first connection line is connected with the data connection electrode.

14. The display substrate according to claim 13, wherein the at least one circuit unit further comprises a data connection block, a first end of the data connection block is connected with the first connection line, and a second end of the data connection block is connected with the data connection electrode.

15. The display substrate according to claim 14, wherein in at least one circuit unit, the first connection line, the data connection electrode, and the data connection block are disposed in a same layer and are of an interconnected integral structure.

16. The display substrate according to claim 1, wherein at least one circuit unit further comprises a second initial signal line extending along the first direction and a second initial connection line extending along the second direction, the second initial connection line is disposed between two second initial signal lines adjacent in the second direction and is respectively connected with the two second initial signal lines to form a second initial signal line with a network communication structure in the display region.

17. The display substrate according to claim 16, wherein the second initial connection line is disposed in an odd-numbered unit column, or the second initial connection line is disposed in an even-numbered unit column;
or,
the second initial signal line and the second initial connection line are disposed in a same layer and are of an interconnected integral structure.

18. The display substrate according to claim 16, wherein in two adjacent unit rows, a unit column in which the second initial connection line is located in one unit row is different from a unit column in which the second initial connection line is located in the other unit row.

19. (canceled)

20. The display substrate according to claim 1, wherein the pixel drive circuit at least comprises a storage capacitor and a plurality of transistors, and the plurality of conductive layers comprise a shielding layer, a first semiconductor layer, a first gate metal layer, a second gate metal layer, a second semiconductor layer, a third gate metal layer, a first source-drain metal layer, a second source-drain metal layer, and a third source-drain metal layer disposed sequentially along a direction away from the base substrate; the shielding layer at least comprises a shielding electrode, the first semiconductor layer at least comprises active layers of a plurality of low temperature poly silicon transistors, the first gate metal layer at least comprises a first scan signal line, a light emitting signal line, and a first electrode plate of a storage capacitor, the second gate metal layer at least comprises a second electrode plate of the storage capacitor, the second semiconductor layer at least comprises active layers of a plurality of oxide transistors, the third gate metal layer at least comprises a second scan signal line and a third scan signal line, the first source-drain metal layer at least comprises a second initial signal line with a network communication structure, the second source-drain metal layer at least comprises a shielding electrode and the first connection line, and the third source-drain metal layer at least comprises a first power supply line, the data signal line, and the second connection line.

21. The display substrate according to claim 20, wherein the plurality of transistors comprise a first transistor, a second transistor, a third transistor, a fourth transistor, a fifth transistor, a sixth transistor, and a seventh transistor, the first transistor and the second transistor are oxide transistors, and the third transistor, the fourth transistor, the fifth transistor, the sixth transistor, and the seventh transistor are low temperature poly silicon transistors.

22. A display apparatus, comprising a display substrate according to claim 1.

23. A preparation method of a display substrate, wherein the display substrate comprises a display region and the preparation method comprises:
forming a drive structure layer on a base substrate of the display region, wherein the drive structure layer at least comprises a plurality of circuit units constituting a plurality of unit rows and a plurality of unit columns, a plurality of data signal lines extending along a second direction, a plurality of first connection lines extending along a first direction, and a plurality of second connection lines extending along the second direction, the first direction intersects with the second direction; a circuit unit comprises a pixel drive circuit, at least one data signal line is connected with a plurality of pixel drive circuits of a unit column, first ends of the plurality of first connection lines are correspondingly connected with the plurality of data signal lines, and second ends of the plurality of first connection lines are correspondingly connected with the plurality of second connection lines; pixel drive circuits in adjacent unit columns are mirror symmetrical with respect to a center line, the center line is a straight line located between adjacent unit columns and extending along the second direction, and a second connection line is disposed at a gap between pixel drive circuits of adjacent unit columns.
